(19) United States
(12) Patent Application Publication
(10) Pub. No.: US 2007/0164387 A1
(43) Pub. Date: Jul. 19, 2007

(54) Imaging system for correcting dark level with high accuracy

(75) Inventor: Yoshinori Furuta, Asaka-shi (JP)

Correspondence Address: BIRCH STEWART KOLASCH & BIRCH, PO BOX 747, FALLS CHURCH, VA, 22040-0747, US

(73) Assignee: FUJIFILM Corporation

(21) Appl. No.: 11/652,542

(22) Filed: Jan. 12, 2007

(30) Foreign Application Priority Data
Jan. 19, 2006 (JP) 2006-11126

(51) Int. Cl. H01L 31/00

(52) U.S. Cl. 257/442

(57) ABSTRACT

A digital camera is provided that includes an image pick-up subsection whose CCD includes a shaded sub-pixel, and a signal processor that includes a dark processor and a sub-signal processor. The digital camera acquires a dark current in an effective pixel area and a leak signal or leak data during reading out signal charges to correct images.

### BACK GROUND OF THE INVENTION

1. Field of the Invention

The present invention relates to an image sensor and an imaging system, and in particular, to an image sensor for capturing an image with its dynamic range broader than usual images, the dynamic range being one of the characteristics of an image obtained by image capturing. The present invention also relates to an imaging system using the image sensor that may provide a wider dynamic range, such as a solid-state image pickup device and an image input device.

2. Description of the Background Art

The digital camera and video camera use an image sensor. The image sensor outputs a signal component under a shaded condition where, for example, the lens is completely stopped down, i.e., no light is incident, as in the condition where weak light is incident. The signal component depends on a dark current generated by, for example, the drive circuit built in the image sensor. Such a signal component is referred to as the dark shading. The process for addressing the signal component is disclosed by Japanese Patent Laid-Open Publication No. 2000-350091, entitled “IMAGE PICKUP DEVICE AND SIGNAL PROCESSING THEREFOR.” The disclosed process is taking data under the entirely shaded condition and during shooting, comparing the data during shooting with the data under the entirely shaded condition, and subtracting the data under the entirely shaded condition from the data during shooting in order to remove and correct the effect of the dark shading.

The image sensor has an optical black (OB) area formed around the effective pixel area. The image sensor takes the reference dark current from the optical black area. The dark shading may be corrected by using the reference dark current to compare the data corresponding to the reference dark current with the data from the effective pixel area.

One existing proposal presents for the image sensor a solid-state image pickup device to increase the dynamic range of a shot image. Specific examples of the solid-state image pickup device are disclosed by U.S. Patent Application Publication No. US 2003/0141564 Al to Kondo et al., and Japanese Patent Laid-Open No. 117281/1991. The solid-state image pickup device has an array of two types of photosensitive devices: a main pixel and a sub-pixel. The main pixel has its photoelectric conversion efficiency of converting incident light into signal charges higher than the sub-pixel. The main pixel has its photo-sensitive area for the photoelectric conversion broader than the sub-pixel to implement the higher photoelectric conversion efficiency.

The dark shading is corrected using the data under the entirely shaded condition with an additional procedure added. The procedure is that the image sensor shoots before the actual image shooting under the entirely shaded condition to take data for the entirely shaded condition. It thus needs a longer time before the actual shooting. A shutter time lag thus occurs between the shutter. timing desired by the user and the shutter timing when the shutter is actually operated.

If the actual shooting is followed by the shooting under the entirely shaded condition, more time is needed to complete the actual shooting, thus taking a long time for the user to watch the shot image displayed. The continuous shooting done with this procedure will reduce the continuous shooting speed.

When use is made of the data taken in advance under the entirely shaded condition, an excessively long time lapse between the shooting under the entirely shaded condition and the actual shooting makes it difficult to evaluate the effect of the image sensor temperature or the like in the data. The image sensor thus corrects the dark shading but with reduced accuracy.

When the data of the optical black area is used, the dark shading in the horizontal direction of an image may be corrected using the data from the optical black area in the same row as the effective pixel area, and the dark shading in the vertical direction may be corrected using the data from the optical black area in the same column as the effective pixel area. The peripheral area of the effective pixel area close to the optical black area may provide the dark shading with the requested accuracy. The central portion of the effective pixel area far from the optical black area or the like may, however, provides the dark shading with poor accuracy.

### SUMMARY OF THE INVENTION

It is an object of the present invention to provide an image sensor and an imaging system that may provide more accurate dark correction than the conventional technologies for the area far from the optical black area.

The present invention provides an image sensor comprising: a plurality of photosensitive devices that photoelectrically convert incident light from a field of view into signal charges, each of the photosensitive devices having a first photosensitive area defined as a main pixel and a second photosensitive area defined as a sub-pixel and smaller than the first photosensitive area; a color filter segment of a predetermined color that passes a predetermined wavelength range included in the incident light, and is provided correspondingly to the main pixel and the sub-pixel; a column transfer path that selectively transfers, in a vertical direction, the signal charges generated by the main pixel and the sub-pixel and read into the column transfer path, wherein the photosensitive devices include an effective area for being finally used to produce an image of the field of view, and ones of the sub-pixels in the effective area are shaded to form shaded sub-pixels.

The present invention also provides an imaging system comprising: an image sensor; and a signal processor that carries out signal processing on image data obtained by the image sensor, wherein the image sensor comprises: a plurality of photosensitive devices that photoelectrically convert incident light from a field of view into signal charges, each of the photosensitive devices having a first photosensitive area defined as a main pixel and a second photosensitive area defined as a sub-pixel and smaller than the first photosensitive area; a color filter segment of a predetermined color that passes a predetermined wavelength range included in the incident light, and is provided correspondingly to the main pixel and the sub-pixel; a column transfer path that selectively transfers, in a vertical direction, the signal charges generated by the main pixel and the sub-pixel and read into the column transfer path, the photosensitive devices including an effective area for being finally used to produce an image of the field of view, ones of said sub-pixels in the effective area being shaded to form shaded sub-pixels.

According to the aspects of an image sensor and an imaging system of the present invention, the effective area of the photosensitive device partially includes a shaded sub-pixel, allowing for the measurement of the dark current in the effective area as the reference dark data, the correction of the image based on the reference dark data, and further improvement of the image quality of the shot image.

### BRIEF DESCRIPTION OF THE DRAWINGS

The objects and features of the present invention will become more apparent from consideration of the following detailed description taken in conjunction with the accompanying drawings in which:

FIG. 1 is a block diagram of a schematic configuration of a digital camera in accordance of an illustrative embodiment of the present invention;

FIG. 2 is a block diagram of a schematic configuration of a charge-coupled device (CCD) of an image sensor in accordance with the embodiment shown in FIG. 1;

FIG. 3 is a plan view of a pixel array in the effective pixel area in the CCD shown in FIG. 2;

FIG. 4A is a partial plan view from the top of pixels in the CCD shown in FIG. 2;

FIG. 4B is a cross sectional view along the cutting line IVA-IVA of the pixel in the CCD shown in FIG. 2;

FIG. 4C is a cross sectional view along the cutting line IVB-IVB of the pixel in the CCD shown in FIG. 2;

FIG. 5 is a schematic block diagram of a configuration of the dark acquisition portion shown in FIG. 1;

FIG. 6 is a schematic block diagram of a configuration of the leak acquisition portion shown in FIG. 1;

FIG. 7 is a timing chart of a reading out order of signal charges when continuously shot with the CCD shown in FIG. 2;

FIG. 8A is a graph plotting a dark level of a shaded portion in the CCD shown in FIG. 2;

FIG. 8B is another graph plotting a dark level of a shaded portion in the CCD shown in FIG. 2;

FIG. 9 is a graph of a relation of a main pixel's dark level to a sub-pixel's dark level in the CCD shown in FIG. 2;

FIG. 10A is a graph showing a relation of a main pixel's dark level to a sub-pixel's dark level in the CCD shown in FIG. 2 at low temperatures;

FIG. 10B is a graph showing a relation of a main pixel's dark level to a sub-pixel's dark level in the CCD shown in FIG. 2 at high temperatures;

FIG. 11A is a partial plan view from the top of pixels in a CCD using an image sensor of an alternative embodiment of the present invention;

FIG. 11B is a cross sectional view of pixels in a CCD using an image sensor of the alternative embodiment along the cutting line XI-XI in FIG. 11A;

FIG. 12A illustrates a scene of shooting outdoors in backlight;

FIG. 12B is a graph plotting a sub-pixel's signal level obtained in horizontal sampling of a CCD in a scene of shooting outdoors in backlight;

FIG. 13A illustrates an exemplified scene of shooting outdoors from the room;

FIG. 13B is a graph plotting a sub-pixel's signal level obtained in horizontal sampling of a CCD in a scene of shooting outdoors from the room;

FIG. 14 illustrates an example of a pixel array in the CCD shown in FIG. 2 with shaded sub-pixels provided with blue (B) color-filter segments more than red (R) color-filter segments;

FIG. 15 shows main-pixel gains for respective colors at white positions in the digital camera shown in FIG. 1;

FIG. 16 illustrates an example of a pixel array in the CCD shown in FIG. 2 with most of the shaded sub-pixels provided with green (G) color-filter segments;

FIG. 17A is a graph plotting a dark level of a sub-pixel including a flaw under a shaded condition in the CCD shown in FIG. 2;

FIG. 17B is another graph plotting a dark level of a shaded sub-pixel under a shaded condition in the CCD shown in FIG. 2;

FIGS. 18A and 18B are graphs plotting a sub-pixel's dark level depending on an exposure time and temperature under a shaded condition in the CCD shown in FIG. 2;

FIG. 19 is a flowchart useful for understanding a procedure of determining a dark level in a shaded sub-pixel mode in the CCD shown in FIG. 2;

FIG. 20A is a graph plotting a sub-pixel's signal level obtained when the CCD shown in FIG. 2 is used to image a field of view and the CCD is sampled in the horizontal direction;

FIG. 20B is another graph plotting a sub-pixel's dark level obtained when the CCD shown in FIG. 2 is used to image a field of view and the CCD is sampled in the horizontal direction;

FIG. 21 is a flowchart useful for understanding a procedure of determining a dark level in a non-shaded sub-pixel mode in the CCD shown in FIG. 2;

FIG. 22 illustrates how signal charges are read out from a main pixel to a vertical transfer path in the first field in the CCD shown in FIG. 2;

FIG. 23 illustrates how signal charges are read from a sub-pixel to a vertical transfer path in the second field in the CCD shown in FIG. 2;

FIG. 24 illustrates how signal charges are read from a main pixel to a vertical transfer path and a leak from a sub-pixel to a vertical transfer path in the CCD shown in FIG. 2;

FIG. 25 is a graph plotting a signal level of a main pixel in the CCD shown in FIG. 2 obtained when the CCD is sampled in the horizontal direction;

FIG. 26 illustrates how signal charges are read from a sub-pixel to a vertical transfer path in the third field in the CCD shown in FIG. 2; and

FIG. 27 illustrates how signal charges are read from a main pixel to a vertical transfer path in the fourth field in the CCD shown in FIG. 2.

### DESCRIPTION OF THE PREFERRED EMBODIMENTS

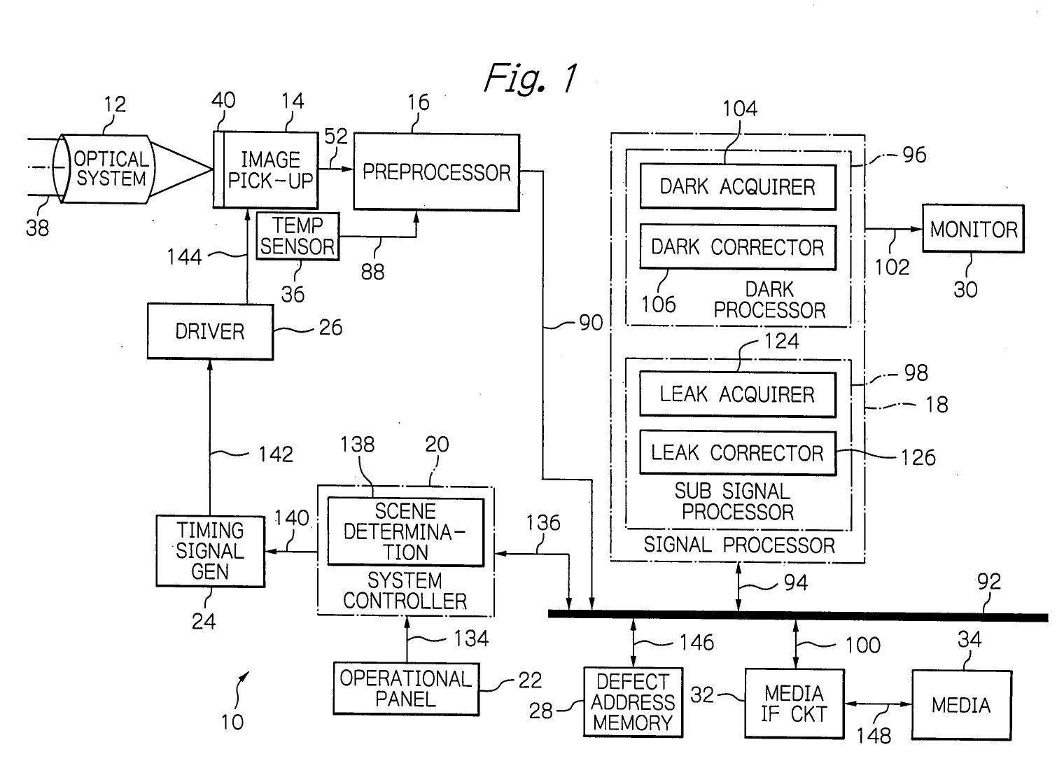

With reference to the accompanying drawings, preferred embodiments of an imaging system of the present invention will be described in more detail. FIG. 1 shows an embodiment of an imaging system of the present invention, in which a digital camera 10 includes an image pick-up section 14 that includes a charge-coupled device (CCD) 40 including shaded sub-pixels, and a signal processor 18 that includes a dark processor 96 and a sub-signal processor 98. These components may acquire a dark current in an effective pixel area and a leak signal or leak data during read of signal charges, thus correcting the image to further improve the image quality.

The instant embodiment is implemented as a digital camera 10 including an image pickup device of the present invention. Illustration and description of the portions are omitted which are not directly related to understanding the present invention.

As shown in FIG. 1, the digital camera 10 includes, in addition to the signal processor 18, an optical system 12, the image pick-up section 14, a preprocessor 16, a system controller 20, an operational panel 22, a timing signal generator 24, a driver 26, a defect address memory 28, a display monitor 30, a media interface (IF) circuit 32, a recoding media 34, and a temperature sensor 36, which are interconnected as illustrated.

The optical system 12 has a function of receiving incident light 38 from the field of view, or imaging field, to focus an image of a certain angle of field in response to the operation of the operational panel 22, onto the imaging plane of the image pick-up section 14. The optical system 12 adjusts the angle of field and focus distance in response to the zoom operation or half-stroke depressing operation of a shutter release key of the operational panel 22.

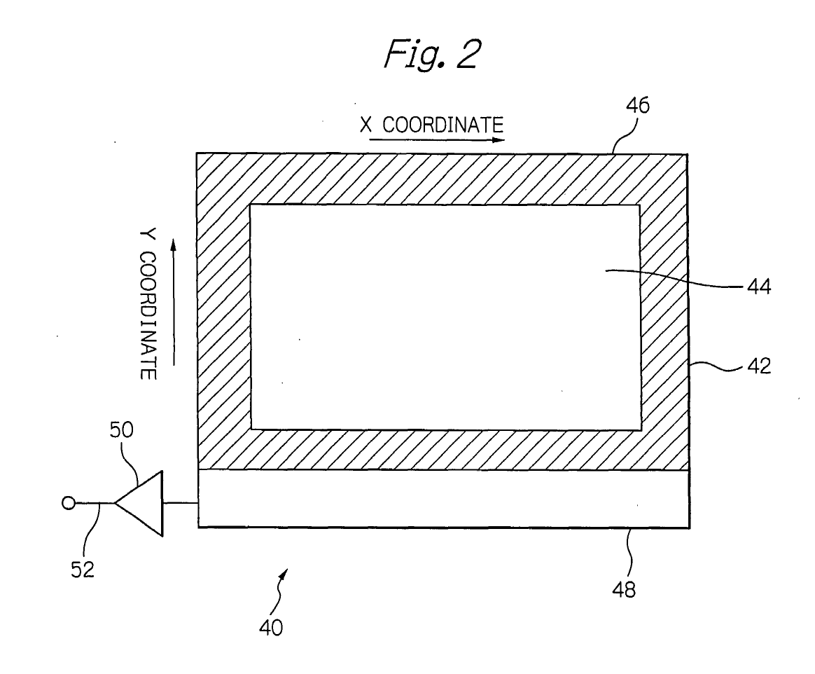

The image pick-up section 14 includes the image sensor 40 of the CCD (Charge Coupled Device) type with the illustrative embodiment. The image sensor 40 includes photosensitive devices or cells, which are two-dimensionally arrayed in the columns and rows to form an imaging plane 42, as shown in FIG. 2. The photosensitive devices may be specified with X and Y coordinates. The imaging plane 42 of the image sensor 40 may be divided into two areas: an effective pixel area 44 on which light is incident and an optical black (OB) area 46 which is an optically shielded, dark area on which no light is incident. The optical black area is shown as a hatched area in FIG. 2. The optical black area 46 is formed to surround the effective pixel area 44.

The image sensor 40 converts, in the effective pixel area 44, the incident light into electrical signal charges. The image sensor 40 reads out, even in the optical black area 46, signals due to various sources as dark currents. The signal charges generated in the effective pixel area 44 are transferred over a vertical transfer path, not-shown, to a horizontal transfer path 48. The horizontal transfer path 48 transfers the signal charges shifted from the vertical transfer path to an amplifier 50. The amplifier 50 is a floating diffusion amplifier that converts the supplied signal charges into analog voltage signals 52 and outputs them. Signals are designated with reference numerals of connections on which they are conveyed. The analog voltage signals 52 are outputted to the preprocessor 16 as the image signals forming the image of the field of view. The analog voltage signals 52 include the image signals as well as a dark-current reference signal indicating the dark current in the optical black area 46.

The dark-current reference signals in the same row and column as the relevant pixel in the effective pixel area 44 have been used for, for example, the dark shading correction in the horizontal and vertical directions, respectively, of the imaging plane. The dark-current reference signal has thus previously been obtained from the vicinity of the effective pixel area 44, as described above. The dark currents on the periphery of the effective pixel area 44 may thus be accurately corrected. The dark currents in the areas far from the optical black area 46 such as the central portion of the effective pixel area 44 may, however, be corrected less accurately.

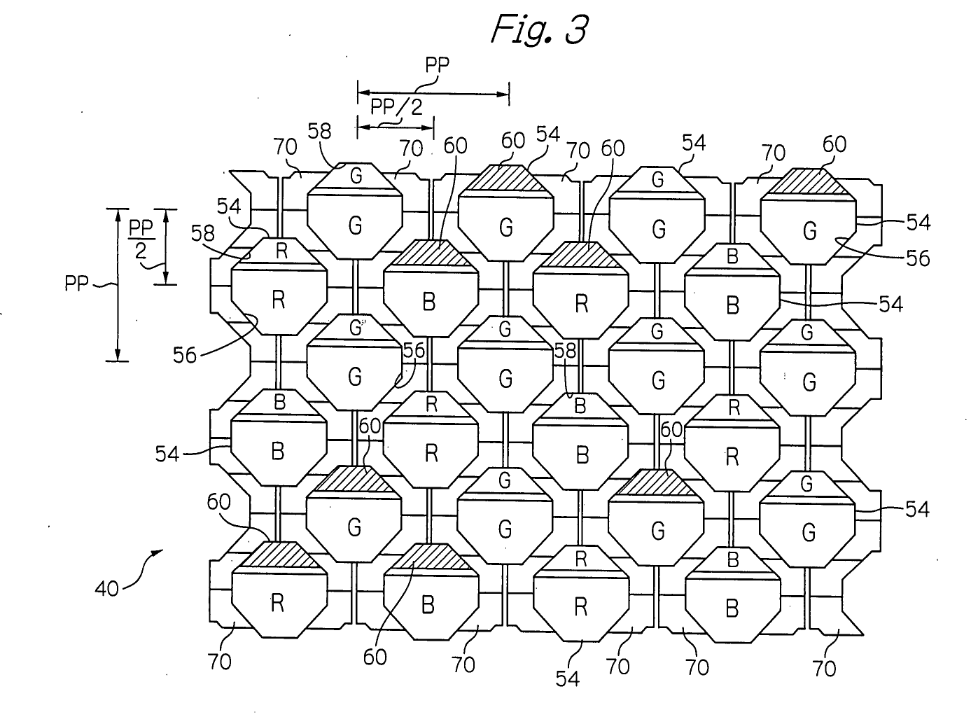

The CCD 40 of the instant embodiment has a function of improving the correction accuracy for the dark currents in such areas. The CCD 40 may implement that function by having, as shown in FIG. 3, some of the photosensitive devices 54 in the effective pixel areas 44 shaded to form the optical black areas.

The CCD 40 has the photosensitive devices 54, FIG. 3, arranged with the pixels shifted to each other, i.e., arranged in a so-called honeycomb pattern. The arrangement has adjacent rows of the photosensitive devices 54 with the photosensitive devices 54 arranged at an interval PP in both rows, and the photosensitive devices 54 in one row basically are offset from the photosensitive devices 54 in the other row by half the interval PP. The CCD 40 may have the photo sensitive devices arranged more densely to improve the image resolution.

Each photosensitive device 54 is divided, unlike the usual photosensitive devices, into two areas: a main pixel area 56 and a sub-pixel area 58, for example. In this embodiment, the main pixel area 56 may sometimes be referred to as a main pixel and the sub-pixel area 58 is referred to as a sub-pixel. The main pixel area 56 has, compared to the sub-pixel area 58, a much larger photo-sensitive area, which may generate more signal charges. The main and sub-pixels have the photo-sensitive areas thereof which are different from each other to generate different amounts of signal charges. The main and sub-pixels may be of the type generating different amounts of signal charges with micro lenses having a light-collection function provided or not on the top of the photosensitive devices 54 to which the incident light comes. Additionally or alternatively, the main and sub-pixels maybe formed of materials providing different light sensitivities.

The CCD 40 includes color filter segments on the side where light is incident and between the micro lenses and photosensitive devices 54. The color filter segments are in a one-to-one relation with the photo sensitive devices 54. The color filter segments have a function of separating the incident light into different colors depending on the spectral characteristics of the light. The color filter segment of this embodiment uses the three primary colors: red (R), blue (B), and green (G). The color G filter segments are arranged in a square or tetragonal lattice. The color Rand B color filter segments are also arranged in square lattices, respectively, which together form a full-checkered pattern. The entire color filter pattern is referred to as a G square lattice RB checkered pattern. The color filter segment provides the same color for the main and sub-pixels in one photosensitive device 54. The color filter segment is not limited to of the three primary colors, but may be of the complementary colors.

The CCD 40 of the illustrative embodiment shades a portion of the photosensitive device 54 that is formed in an area far from the optical black area 46. The shading is carried out using the sub-pixel area 58, as shown in FIG. 3. The sub-pixel areas 58 that are shaded are hereinafter referred to as the shaded sub-pixels 60,which are shown as hatched areas in FIG. 3. The shaded sub-pixels 60 may be arranged, for example, every other column in a row of the color G. In a row adjacent to the shaded sub-pixel 60 of the color G, two adjacent shaded sub-pixels each having the color R or B filter segment are arranged for every ten shaded sub-pixels 60 of the color G. The shaded sub-pixels 60 are arranged every other row in a column direction.

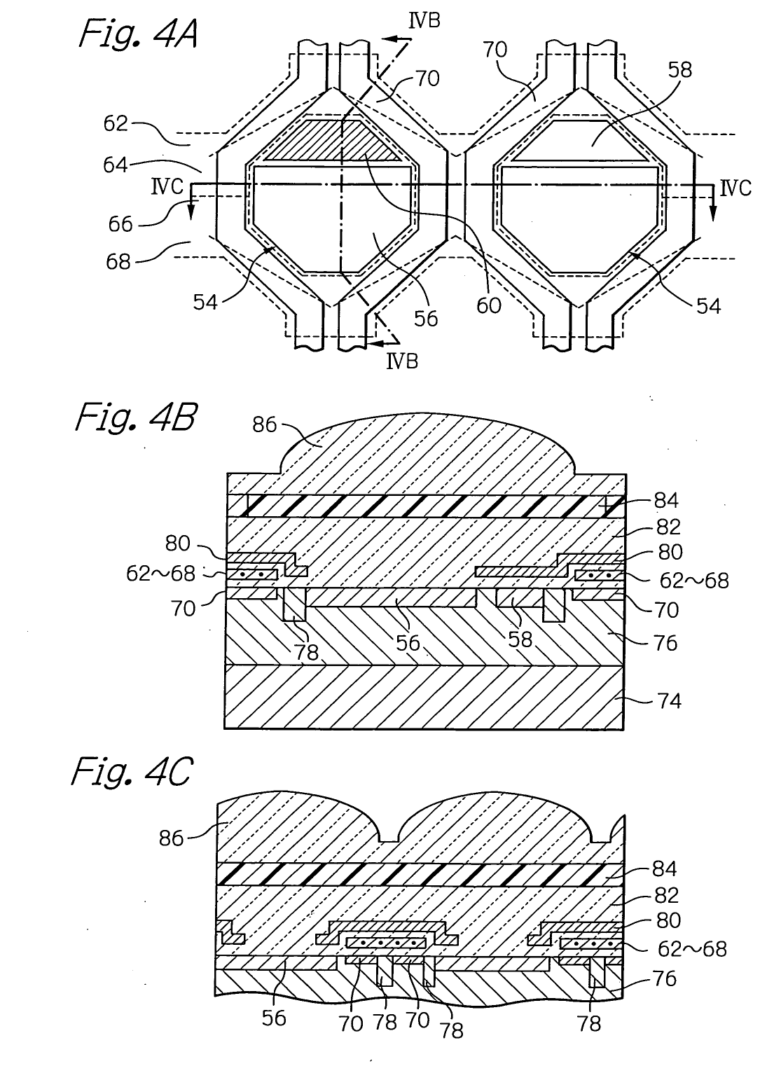

A structure of the photosensitive device is shown in FIGS. 4A, 4B and 4C. FIG. 4A shows the photosensitive device 54 that includes two photosensitive devices 54 disposed horizontally: the left one has the shaded sub-pixel 60 and the right one has no shaded sub-pixel 60. The dotted lines in FIG. 4A show poly-crystalline silicon, or polysilicon, electrodes 62, 64, 66 and 68. The polysilicon electrodes 62, 64, 66 and 68 are arranged across over the vertical transfer path 70. When two-layer polysilicon is used for the transfer electrode, the first layer includes the polysilicon electrodes 62 and 66, and the second layer includes the polysilicon electrodes 64 and 68, each electrode being used for the transfer electrode. The transfer electrode 64 controls the charge read out from the shaded sub-pixel are a 60 and sub-pixel area 58 to the vertical transfer path 70. The other transfer electrode 66 controls the charge read out from the main pixel 56 to the vertical transfer path 70.

FIGS. 4B and 4C show cross sections along the dot-and-dash lines IVB-IVB and IVC-IVC in FIG. 4A, respectively. The photosensitive device 54 has an n-type semiconductor substrate 74 on which a p-type well 76 is formed. The p-type well 76 has, in turn, n-type areas formed thereon, which correspond to the main pixel area 56 and sub-pixel area 58, respectively. The p+ area is a channel stop 78, which electrically isolates the main pixel, sub-pixel, and vertical transfer path 70 and the like from each other. The cross section in FIG. 4B shows the channel stop 78 and the vertical transfer path 70 outside of it. The vertical transfer path 70 has the transfer electrodes 62 to 68 formed thereover. In FIG. 4C, the p-type well 76 between the main pixel 56 and vertical transfer path 70 and the p-type well 76 between a not-shown sub-pixel and the vertical transfer path 70 correspond to reading gates.

The vertical transfer path 70, channel stop 78, main pixel area 56, and sub-pixel area 58 have insulating layers formed thereover, such as a silicon dioxide film. The insulating layers have the transfer electrodes 62 to 68 formed there over. The transfer electrodes 62 to 68 are formed to cover the vertical transfer path 70, as described above. The transfer electrodes 62 to 68 are covered by, for example, silicon dioxide and the like. To shade the vertical transfer path 70, a shading film 80 of tungsten or the like is formed. In the photosensitive device 54 shown in FIG. 4B, the shading film 80 is formed to cover areas except the main pixel area 56. In the right photosensitive device 54 that has no shaded sub-pixel 60, the shading film 80 is formed to cover areas except the main pixel area 56 and sub-pixel area 58. After the shading film 80 is thus formed, the interlayer dielectric 82 is formed and its surface is planarized. The interlayer dielectric 82 is formed of an optically transparent member such as phosphosilicate glass.

The interlayer dielectric 82 has the color filter segment formed thereon for each color, the color filter segment being formed as a color filter layer 84. Although this embodiment has the main pixel area 56 and sub-pixel area 58 covered by the color filter layers 84 of the same color, different color filter layers 84 may also be used. The color filter layer 84 has a micro lens 86 formed there on. The micro lens 86 has a function of collecting or converging the incident light into an opening corresponding to the photo-sensitive area.

Returning to FIG. 3, the CCD 40 includes the transfer path 70, which transfers the signal charges obtained at the photosensitive device 54 in the vertical direction. Because the photosensitive devices 54 are arranged with the pixels shifted to each other, the vertical transfer path 70 is formed to bypass the photosensitive devices 54 and run in a zigzag line. The CCD 40 uses various signals including drive signals V1 to V4 supplied from the driver 26 to read out, transfer, and output the signal charges. In short, the CCD 40 converts or transduces the incident light during exposure to the electrical signal, reads out the accumulated signal charges to each vertical transfer path 70, and transfers the charges to the horizontal transfer path 48. The signal charges at the lowest stage, on the imaging plane, of each vertical transfer path 70 are line-shifted to the horizontal transfer path 48. The signal charges are transferred over the horizontal transfer path 48 to the amplifier 50. The amplifier 50 converts the supplied signal charges to the analog electrical voltage signal and outputs the latter to the preprocessor 16.

The CCD 40 of this embodiment reads out, in the continuous shooting mode, the signal charges from the photosensitive device 54 to the vertical transfer path 70 by selecting, for each frame, the pixels to read out in the order of the main pixel, sub-pixel, sub-pixel, and main pixel, and so on. The signal charges may be read out in this way by generating a timing signal under the control of the system controller 20, and by applying to the CCD 40 a field-shift gate pulse in response to the timing signal.

Returning now to FIG. 1, the image pick-up section 14 including the CCD 40 supplies the analog electrical signal 52 for the obtained image to the preprocessor 16. The instant embodiment provides the temperature sensor 36 in the vicinity of the image pick-up section 14. The temperature sensor 36 outputs a signal 88 representative of a measured temperature to the preprocessor 16.

The preprocessor 16 has an analog front-end (AFE) function. The AFE function includes the functions of the noise reduction of the analog electrical signal 52 using the correlated-double sampling (CDS) and of the digitization, i.e., the analog-to-digital (A/D) conversion of the noise-reduced analog electrical signal 52. The preprocessor 16 outputs the digitized image data 90 over the bus 92 and signal line 94 to the signal processor 18.

The signal processor 18 has the ordinary functions such as synchronizing the supplied image data and using the synchronized image data to produce a luminance and chrominance (Y/C) signal. The signal processor 18 includes the dark processor 96 and sub-signal processor 98. The signal processor 18 also has a function of converting the generated Y/C signal to, for example, a signal appropriate for the liquid crystal display monitor. The signal processor 18 also has the functions of compressing, depending on the record mode, the produced Y/C signal, and of expanding the compressed signal for the restoration and reproduction. There cord mode may include JPEG (Joint Photographic Experts Group), MPEG (Moving Picture Experts Group), and raw data modes and the like. The signal processor 18 supplies the image data processed in a record mode, over the signal line 94, bus 92, and signal line 100, to the media interface circuit 32. The signal processor 18 outputs a signal 102 for the liquid crystal monitor to the monitor 30.

Characteristic functions of the signal processor 18 of the present embodiment will be described below. The dark processor 96 has a function of acquiring data for the dark data correction and correcting the dark data based on the acquired data. The sub-signal processor 98 has a function of responding to the data of the main pixel that corresponds to the shaded sub-pixel 60 and the data of the main pixel that corresponds to the non-shaded sub-pixel in the vicinity of the shaded sub-pixel 60 to determine the amount of signal leaking from the non-shaded sub-pixel to the main pixel.

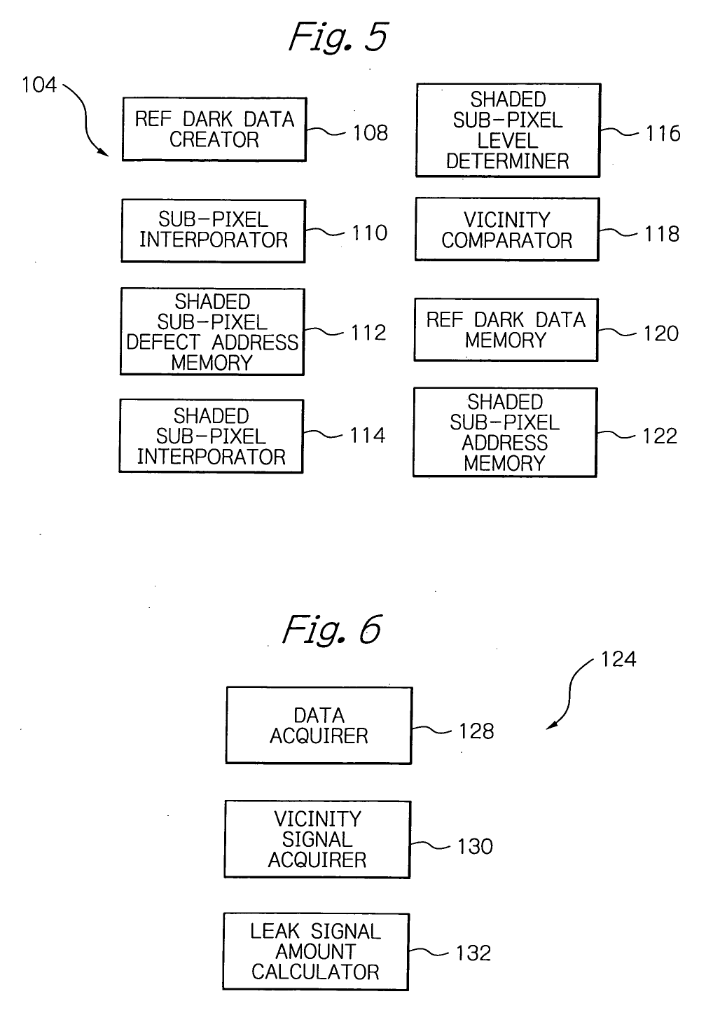

The dark processor 96 includes a dark acquirer 104 and a dark corrector 106. The dark acquirer 104 has a function of acquiring data for the dark data correction. In order to acquire the dark data, the dark acquirer 104 includes, as shown in FIG. 5, a reference dark data creator 108, a sub-pixel interpolator 110, a shaded sub-pixel defect address memory 112, a shaded sub-pixel interpolator 114, a shaded sub-pixel level determiner 116, a vicinity comparator 118, a reference dark data memory 120, and a shaded sub-pixel address (or coordinate) memory 122.

The reference dark data creator 108 has a function of creating, as reference dark data, data corresponding to the dark current obtained randomly from the shaded sub-pixel. The reference dark data creator 108 has a function of using the results from the vicinity comparator 118 to determine that, if the shaded sub-pixel has a defect or flaw, the data from that shaded sub-pixel should not be used as the reference dark data. The sub-pixel interpolator 110 has a function of acquiring the sub-pixel data from the non-shaded sub-pixels in the vicinity of the shaded sub-pixel 60, and using the acquired sub-pixel data as a basis to interpolate sub-pixel data of the shaded sub-pixel 60 that would be obtained if the shaded sub-pixel 60 was not shaded.

The shaded sub-pixel defect address memory 112 has a function of holding the coordinate data of the shaded sub-pixel having a flaw. The shaded sub-pixel defect address memory 112 may store information on a flaw that occurs after shipping the CCD 40. The shaded sub-pixel interpolator 114 has a function of interpolating the sub-pixel data of a shaded sub-pixel having a flaw or an inappropriate signal level based on the sub-pixel data from the vicinity shaded sub-pixels. The shaded sub-pixel level determiner 116 has a function of comparing the pixel data acquired from the shaded sub-pixel with the pixel data, i.e., the signal level, from the vicinity shaded sub-pixels to determine whether or not the pixel data acquired from the shaded sub-pixel is appropriate.

The vicinity comparator 118 has a function of comparing, depending on the condition, the data from the non-shaded sub-pixels in the vicinity of the relevant shaded sub-pixel, and determining whether or not the data from the vicinity non-shaded sub-pixels are appropriate. The condition means that even when the relevant shaded sub-pixel has a flaw, the sub-pixel is available as the shaded sub-pixel if the vicinity non-shaded sub-pixels have signal levels appropriate as the dark data.

The reference dark data memory 120 has a function of storing, for example, the data of each shaded sub-pixel that is acquired before shipping. The reference dark data memory 120 is referenced and used when it is determined that the interpolated data obtained by the shaded sub-pixel interpolation process is inappropriate. The shaded sub-pixel address memory 122 has a function of storing each shaded sub-pixel's coordinate or address.

Returning to FIG. 1, the dark corrector 106 has a function of correcting the dark data based on the data acquired in the dark acquirer 104. The acquired data is used as the dark reference signal.

The sub-signal processor 98 includes a leak acquirer 124 and a leak corrector 126. The leak acquirer 124 has a function of acquiring the amount of signal that leaks into the main pixel's signal from the sub-pixel. The leak acquirer 124 includes, as shown in FIG. 6, a data acquirer 128, a vicinity signal acquirer 130, and a leak signal amount calculator 132. The data acquirer 128 has a function of acquiring the data from the main pixel that pairs with the shaded sub-pixel. The vicinity signal acquirer 130 has a function of acquiring the data from, rather than the main pixel that pairs with the shaded sub-pixel, the main pixels that pair with the non-shaded sub-pixels in the vicinity of the shaded sub-pixel. The leak signal amount calculator 132 has a function of using the-main pixel's data acquired by the data acquisition portion 128 and the main pixel's data acquired by the vicinity signal acquirer 130, and calculating the amount of signal that leaks from the sub-pixel into the main pixel during the reading of the main pixel.

The leak corrector 126 has a function of using the acquired data to correct the signal that leaks from the sub-pixel into the main pixel.

Returning again to FIG. 1, the system controller 20 has a function of generating various control signals in response to the operation signals 134 from the operational panel 22 as described below. The system controller 20 has a function of generating control signals in response to the various settings such as, particularly, the still image mode, automatic exposure (AE) mode, and automatic focusing (AF) mode. The system controller 20 receives the evaluation data obtained in the signal processor 18. The evaluation data is transferred, over the signal line 94, bus 92, and signal line 136, by the system controller 20. The system controller 20 includes a scene determination function portion 138 that carries out the scene determination based on the incorporated evaluation data. The scene determination function portion 138 carries out the scene determination depending on the situations such as in backlight, in front light, under the sun, in a shade, and metal reflection, and feeds the control signal corresponding to the scene determination result also back to the signal processor 18 for the control. The system controller 20 generates a control signal 140 corresponding to the setting mode and evaluation data, and outputs the control signal 140 to the timing signal generator 24.

The operational panel 22 includes a power supply switch, a zoom button, a menu display selector switch, a selection key, a motion picture mode setting portion, a continuous shooting speed setting portion, and a shutter release button, which are not shown specifically. The operational panel 22 has a function of sending the operation signal 134 as the operation instructions to the user to the system controller 20. The power supply switch is adapted to turn on and off the power supply to the digital camera 10. The zoom button is adapted to modify the viewing angle of an imaging field including a subject to be shot, and adjusts the focus distance of the subject in response to the zooming. The menu display selector switch is adapted to switch the menu and move the selection cursor displayed on the screen of the liquid crystal monitor 30. The menu display selector switch includes, for example, a cross-bar type key. The selection key is manipulated to select the selected menu item.

The motion picture mode setting portion determines whether to display the motion picture on the liquid crystal monitor by, for example, setting a flag value. This setting allows the digital camera 10 to display the image of the field of view captured on the monitor 30 as a through image.

The shutter release button has a faction of selecting, in response to the half- and full-stroke depressing operations, the operation timing and operation mode of the digital camera 10. The shutter release button allows, in response to the half pressing operation, the digital camera 10 to operate in the AE or AF mode. These operations determine, using the images in the motion picture display, the appropriate aperture, shutter speed, and focus distance. The shutter release button sends, in response to the full pressing operation, the timing of the record start and stop to the system controller 20 to provide the operation timing depending on the setting mode of the digital camera 10. The setting mode includes the still image record, continuous shooting, and motion picture record modes and the like.

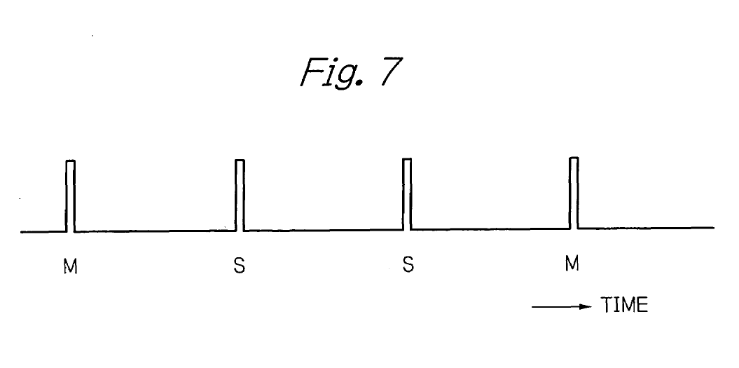

The timing signal generator 24 has a function of generating various timing signals such as the vertical and horizontal synchronization signals, field shift gate signal, vertical and horizontal timing signals, and OFD (Over-Flow Drain) signal for the image pick-up section 14. The function generates various timing signals 142 in response to the control signals 140 from the system controller 20. The timing signal generator 24 outputs the various timing signals 142 to the driver 26. The timing signal generator 24 generates and outputs the timing signals 142 to read out the image in multiple fields. In particular, the timing signal generator 24 generates, in the continuous shooting mode, the timing signal to read the main and sub-pixels in a varied order. The timing signal generator 24 reads out, as shown in FIG. 7, one image in two fields and generates the timing signal 142, in continuously shooting two images, in the order of the main pixel (M), sub-pixel (S), sub-pixel (S), and main pixel (M).

The driver 26 has a function of generating, using the various supplied timing signals 142, vertical and horizontal drive signals corresponding to the drive mode, and the like. The driver 26 outputs a drive signal 144 corresponding to the supplied control signal to the CCD 40 described above in the image pick-up section 14. The driver 26 also generates, depending on the control signal, a drive signal for zooming operation that reduces the field of view formed by the optical system 12 for the telescopic shooting or increases the field of view for the wide angle shooting. The driver 26 then outputs the drive signal to the zooming mechanism, not shown, of the optical system 12.

The defect address memory 28 has a function of holding the coordinate position, or address, of the pixel having a flaw. Particularly, the flaw coordinate position is represented by the address on the coordinate of the flaw of the non-shaded main and sub-pixels. The defect address memory 28 reads out, over the signal line 136, bus 92, and signal line 146, the coordinate of the flawed pixel as appropriate under the control of the system controller 20. The defect address memory 28 then sends the coordinate, over the signal line 146, bus 92, and signal line 94, to the signal processor 18. The signal processor 18 uses the data of the pixels in the vicinity of the read out flaw coordinate to interpolate the data of the flawed pixel to provide the appropriate image.

The display monitor 30 includes a liquid crystal display monitor or the like. The monitor 30 visualizes the image signal 102 supplied from the signal processor 18 to display the image on its display screen, not shown.

The media interface circuit 32 has an interface control function that controls, for example, the record and reproduce of the image data depending on the recording media handled. The media interface circuit 32 may control the read and write of the image data 148 to semiconductor recording media, such as a PC (Personal Computer) card, and may control the read and write with the USB (Universal Serial Bus) controller built therein. The media 34 may include the semiconductor cards of various specifications.

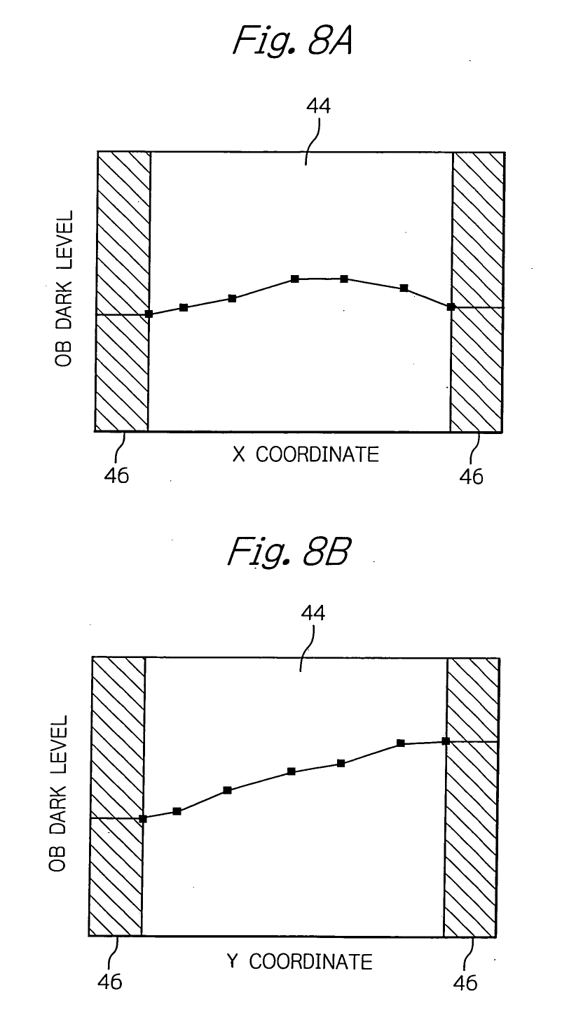

FIGS. 8A and 8B show the dark level obtained in the effective pixel area 44 in the CCD 40. The dark level tends to increase with an increase in temperature, although not shown. FIG. 8A shows the dark level on the X coordinate including the optical black area 46 with the closed square symbol. Likewise, FIG. 8B shows the dark level on the Y coordinate including the optical black area 46 with the closed squares. Both dark levels may be obtained with more accuracy than before using the data from the shaded sub-pixel in the effective pixel area 44. It is understood that more shaded sub-pixels in the effective pixel area 44 may further improve the accuracy of the dark level.

Note that in respect of any one photosensitive cells of the CCD 40, the main and sub-pixels have different areas. The relationship between the dark levels of the main and sub-pixels is thus preferably acquired in advance. Data representative of the dark levels measured before shipping the CCD 40 are stored in the reference dark data memory 120. The relationship between the dark levels may be acquired for each exposure time and stored.

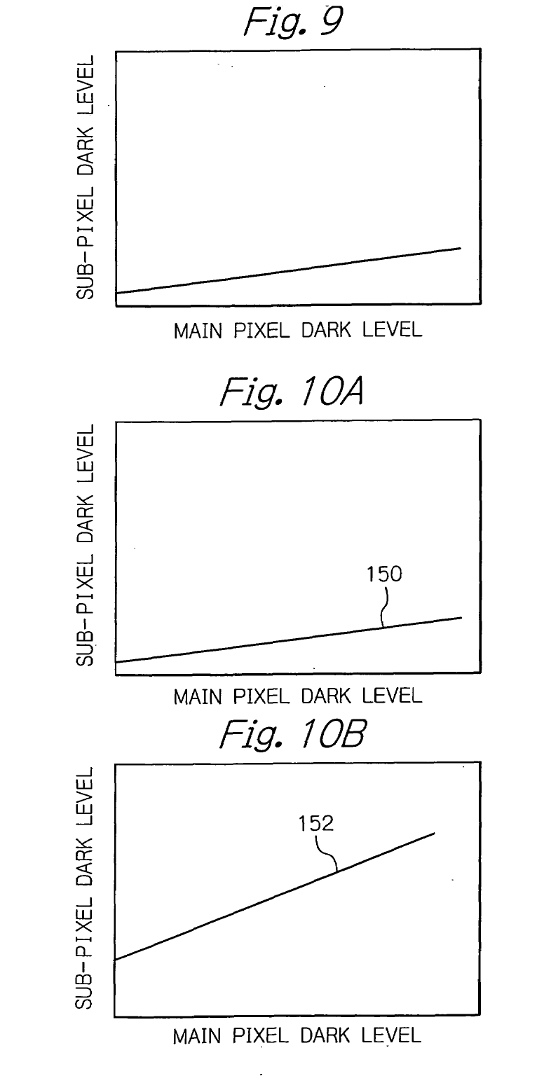

The CCD 40 has a small effect from the dark current from the vertical transfer path 70. The dark levels of the main and sub-pixels have a linear relationship, as shown in FIG. 9, with the dark levels corresponding to the X and Y axis, respectively. The dark levels of the main and sub-pixels may be converted using an area ratio to provide the reference dark level. One dark data may thus provide the other dark level. The memory may thus store a smaller amount of the data.

The CCD 40 increases its dark level with an increase in temperature, as described above. At lower temperatures indicated by the temperature sensor 36, the relationship of the main pixel's dark level to the sub-pixel's dark level is represented by a line 150 with its gradient smaller, as shown in FIG. 10A. The line 150 means a smaller effect from the dark current from the vertical transfer path 70. At high temperatures, the relationship of the main pixel's dark level to the sub-pixel's dark level is represented by a line 152 with its gradient larger, as shown in FIG. 10B. The line 152 means that compared to the lower temperature condition, the dark current generated in the vertical transfer path 70 contributes more largely to the dark level. The dark current generated in the vertical transfer path 70 does not relate to the area of the photosensitive device 54. The main and sub-pixels generate almost the same dark current as shown in FIG. 10B. The reference dark level calculation using the area ratio of the main pixel to sub-pixel may be done safely at low temperatures, but with problems at high temperatures. When, specifically, the correction value of the reference dark level at low temperatures is used for the correction value at high temperatures, it may increase the correction error. The reference dark level is preferably calculated at high temperatures without multiplying the area ratio of the main pixel to the sub-pixel to the level.

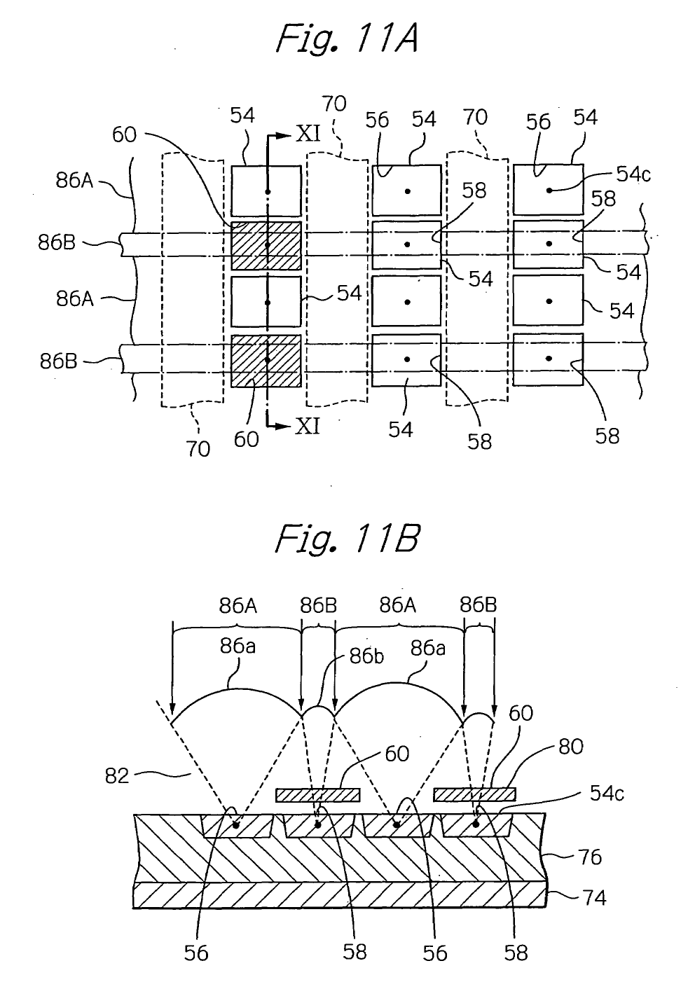

The CCD 40 is not limited to the specific type of photosensitive device 54 arrangement with the pixels shifted to each other. The CCD 40 may not be the type of having the main and sub-pixels in one photosensitive device, but of handling each of the main and sub-pixels as one photosensitive device. In the following description, portions or elements like those of the previous embodiments will be designated with the same reference symbols and their description will be not repeated. The sensitivity difference here depends on the difference of the light gathering power due to the shapes of the micro lens 86. The photosensitive device 54 may include, as shown in FIG. 11, the photo-sensitive areas of the same shape, which may be advantageously easily manufactured. The photo-sensitive areas 56 and 58 each formed as the photosensitive device or cell 54 of this alternative embodiment have the same area, as shown in FIG. 1A. FIGS. 11A and 11B show dots that indicate the centers 54c in the photosensitive devices 54.

FIG. 11B shows a cross section of the CCD 40 along the cutting line XI-XI in FIG. 1A. The CCD 40 includes sequentially, basically as shown in FIG. 4, the substrate 74, the layer 76, and the photo-sensitive layers including the photo-sensitive areas 56 and 58 as the photosensitive devices 54. The shaded sub-pixel 60 is the ordinary sub-pixel with the shade member 80 is formed thereover. Although, in order to clearly describe the structure of the instant alternative embodiment, the color filter segment is not shown, it is understood that the color filter segment is provided between the photosensitive device 54 and micro lens 86.

The photosensitive device 54 corresponding to the main pixel has a micro lens 86a with a smaller curvature formed thereover. The photosensitive device 54 corresponding to the sub-pixel has a micro lens 86b with a larger curvature formed thereover. The micro lenses 86 thus formed may provide a light collecting area 86A larger than a light collecting area 86B. In the CCD 40, the area difference leads to the light gathering power difference, which causes the sensitivity difference.

The photosensitive device 54 has the same area in the main and sub-pixels, providing the same extent of the dark level generated. The previous embodiments provide the photosensitive device 54 that has different areas between the main and sub-pixels, so that the dark level of each pixel needs to be known in advance. This procedure is advantageously unnecessary in this current embodiment. This embodiment may provide the high accurate reference dark level.

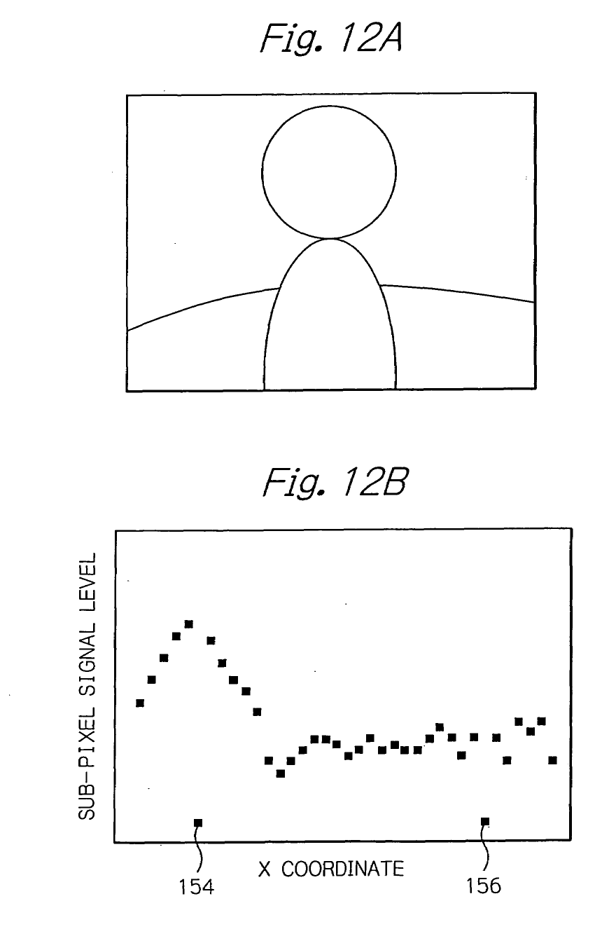

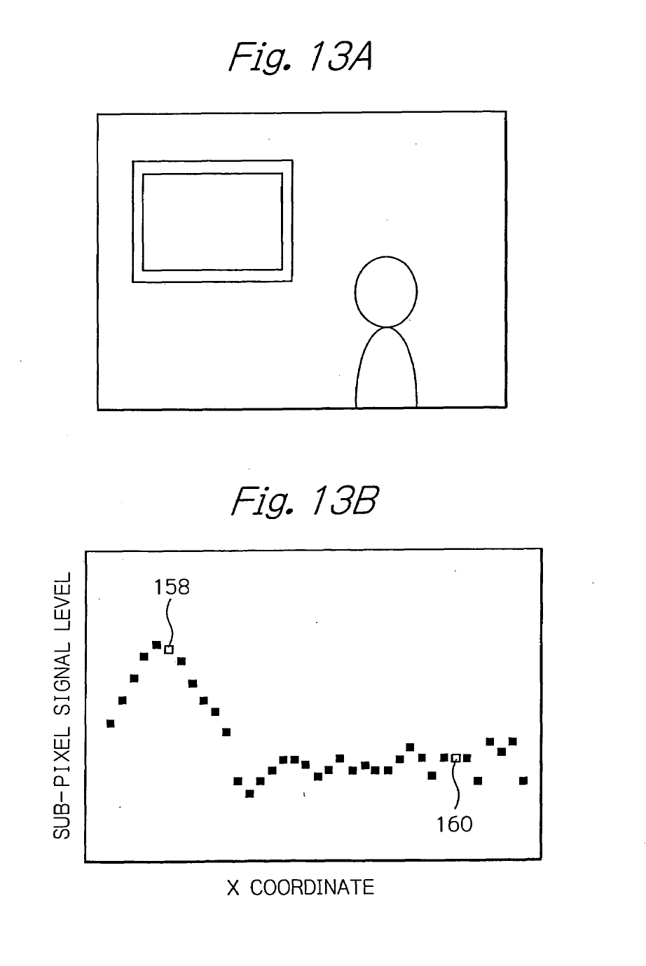

When the CCD 40 is applied to shooting the field of view where the light and dark areas exist together, the CCD 40 requires a dynamic range to reproduce the field of view faithfully as a single image. The dynamic range is checked for by the scene determination in the AE photometry. FIG. 12A shows a scene of shooting outdoors in backlight. FIG. 13A shows a scene of shooting indoors with the field of view including a window through which the light outside is viewed. These scenes tend to include a specific bright or dark area rather than one bright or dark pixel. Using the tendency, the CCD 40 may carry out sampling at a Y coordinate in the horizontal direction to determine the signal levels from the vicinity non-shaded sub-pixels. The data from the shaded sub-pixel obviously has a different signal level from the data from the non-shaded sub-pixel, as shown in FIG. 12B. The data from the shaded sub-pixel is acquired, as dark data 154 and 156 of the optical black area at a Y coordinate in the effective pixel area 44, by the dark acquirer 104 of the signal processor 18.

The pixel data 158 and 160 from the shaded sub-pixel are interpolated by the signal processor 18 using the pixel data from the non-shaded pixels in the vicinity of the relevant shaded sub-pixel. The results are represented, for example, by the pixel data 158 and 160 shown as open squares in FIG. 13B. The interpolations are done by the sub-pixel interpolator 110. The dark data in the effective pixel area 44 and the pixel data of the shaded sub-pixel may be calculated without using the horizontal sampling at a Y coordinate, but using the vertical sampling at an X coordinate. The image data may thus be corrected, using the shaded sub-pixels, as the reference dark level for the effective pixel area 44. The shaded sub-pixels after interpolated are not handled as the defects. The, dynamic range may thus be maintained to provide the high quality image.

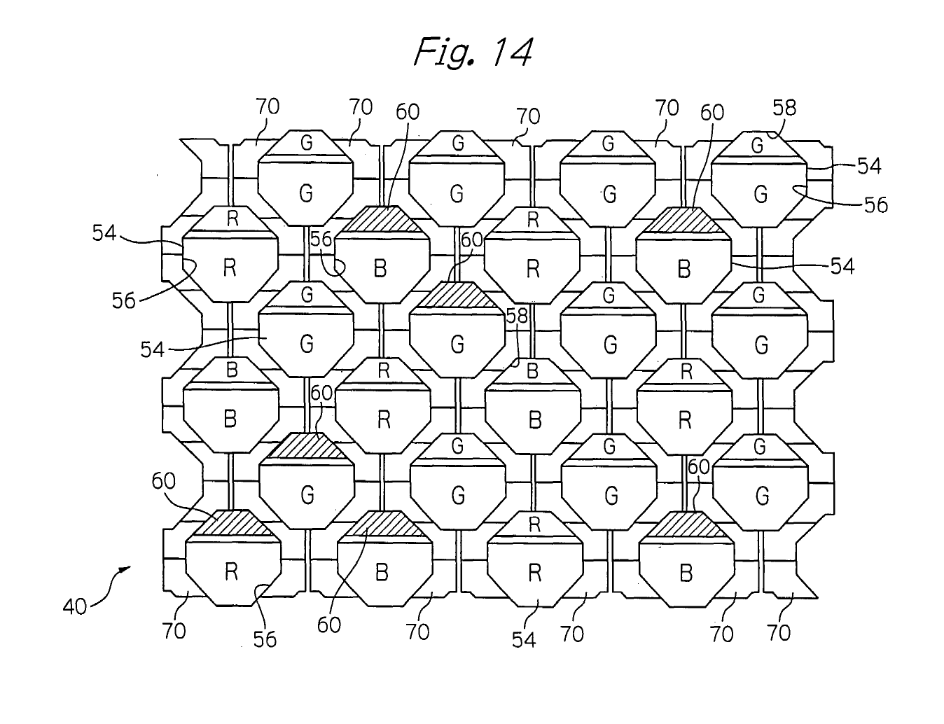

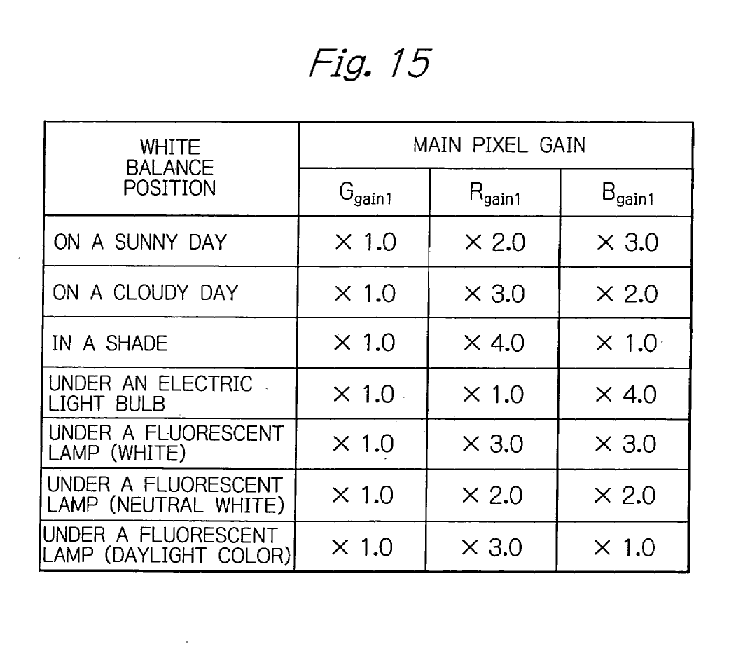

A description will now be given of the ratio of the colors provided to the pixels in the CCD 40 if the shaded sub-pixels included in the CCD 40 are regarded as the non-shaded sub-pixels. Note that the color filter segment provides the same color for the main and sub-pixels, as described in the previous embodiments. FIG. 14 shows an example where the shaded sub-pixels are provided with the segments of color B more than the segments of color R. FIG. 15 shows gains in each scene in white balance positions. Each scene shows the gains for the respective colors. FIG. 15 further shows, in the scenes other than “on a cloudy day”, “in a shade”, and “under a fluorescent lamp (daylight color)”, the gain for the color B larger than the gain for the color R. This means that in the white balance positions, the sensitivity to the color R is higher than the sensitivity to the color B.

In general, the sensitivity to the color R is higher than the sensitivity to the color B in the most of scenes. This means that the color R pixel provides more amount of signal than the color B pixel. The color R pixels are thus used in the scenes with a wide dynamic range. Conversely, in the scenes of “on a cloudy day”, “in a shade”, and “under a fluorescent lamp (daylight color)”, the sensitivity to the color B is higher than the sensitivity to the color R. This means, however, that these scenes provide less amount of signal, meaning that the dynamic range may not be wide. Specifically, except in special circumstances, only a few scenes have a wide dynamic range with the color B pixels.

When the sub-pixels are shaded, the shaded sub-pixels lose the dynamic range. The color B pixel is requested less frequently, however, in the wide dynamic range than the color R and color G pixels. In view thereof, even if more color B sub-pixels are shaded than the color Rand color G sub-pixels, the CCD 40 using the original main pixel and non-shaded sub-pixel may acquire, without losing the characteristic of the wider dynamic range, the dark data and carry out the dark correction to improve the image quality of the image obtained.

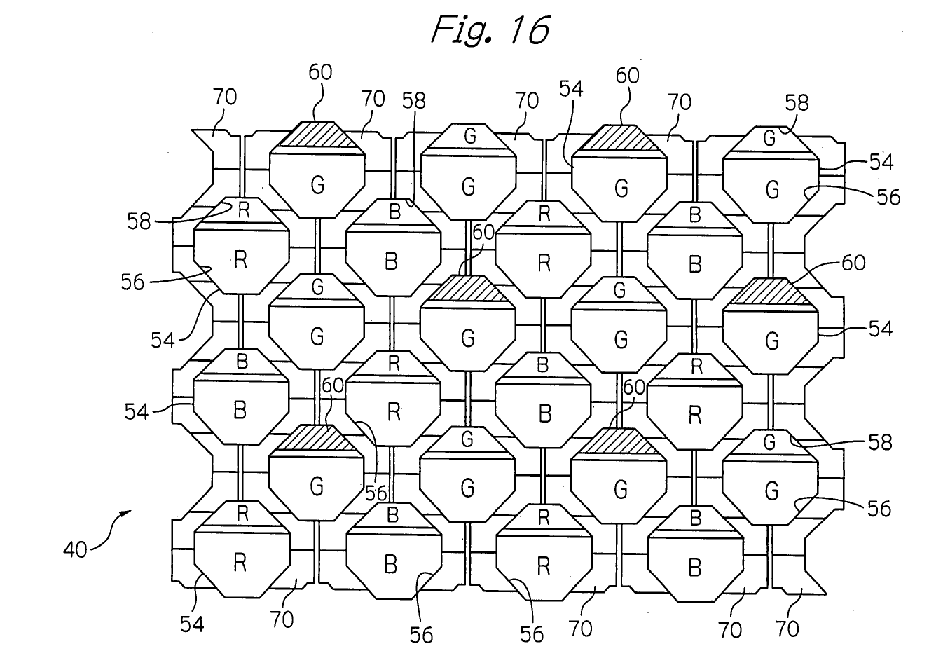

FIG. 16 shows an example of the CCD 40 in which more color G pixels are shaded than the color R and color B pixels. Even when more color G sub-pixels are shaded, the color G pixels are originally more than the others, so their pixel data may be interpolated more easily than the color R and color B shaded pixels based on the pixel data from the vicinity non-shaded pixels. The CCD 40 is thus less affected by the data loss due to the shaded sub-pixels. Because the reference dark data provided in the shaded sub-pixel pattern is hardly affected by color, the data from the color G shaded sub-pixel may be used to determine the dark data of the main pixels in the color R and color B. Using the pattern to carry out the determined dark correction, the image quality may be improved after the dark correction without being affected by color.

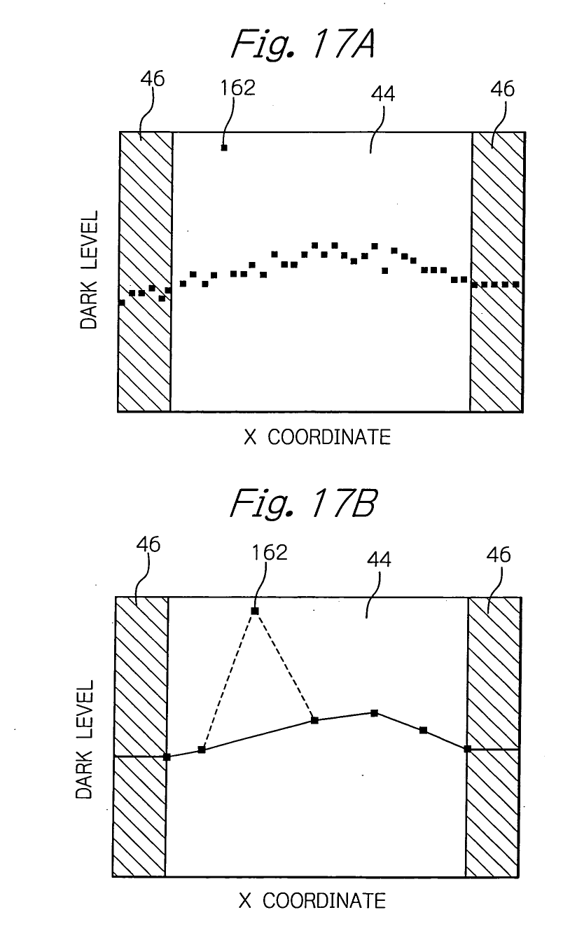

A description will now be given of how to distinguish the shaded sub-pixel and flawed pixel. Suppose that the CCD 40 shoots without any incident light. FIG. 17A shows the dark level in this condition obtained by sampling at a Y coordinate in the horizontal direction, i.e., the X coordinate. The shaded sub-pixel and non-shaded sub-pixel are both within a certain range of the dark level. The shaded sub-pixel 162 having a flaw generates, however, a large amount of dark current even without any incident light, thus providing a high signal level.

FIG. 17B shows the dark level of the shaded sub-pixel. The shaded sub-pixel is used, as described above, to determine the reference dark data of the effective pixel area 44. The reference dark data is data representative of the vicinity pixels. For example, like white flaws, when the pixel originally having the high dark level becomes the shaded sub-pixel, the determination of the vicinity dark level is largely affected.

Whether or not the shaded sub-pixel's dark level is appropriate is determined by the shaded sub-pixel level determiner 116. The shaded sub-pixel level determiner 116 determines, when the level obtained is a predetermined dark level or more, that the pixel is the flawed pixel 162 and should not be used.

When the shaded sub-pixel 162 is known as flawed, the signal processor 18 does not use the data of the shaded sub-pixel 162. Alternatively, the shaded sub-pixel interpolator 114 interpolates the data of the shaded sub-pixel 162 based on the data from the shaded sub-pixels in the vicinity of the shaded sub-pixel 162. The data is obtained at a Y coordinate location in the horizontal direction and also at an X coordinate location in the vertical direction. A combination of the data in both direction coordinates may interpolate the data of the shaded sub-pixel 162 having a flaw. Information on the shaded sub-pixel having a flaw is obtained from the data acquired under the entirely shaded condition before shipping. The information is recorded in the defect address memory 28 and/or the shaded sub-pixel defect address memory 112. The digital camera 10 may record the information in the memories 28 and/or 112 when the camera is turned on or off.

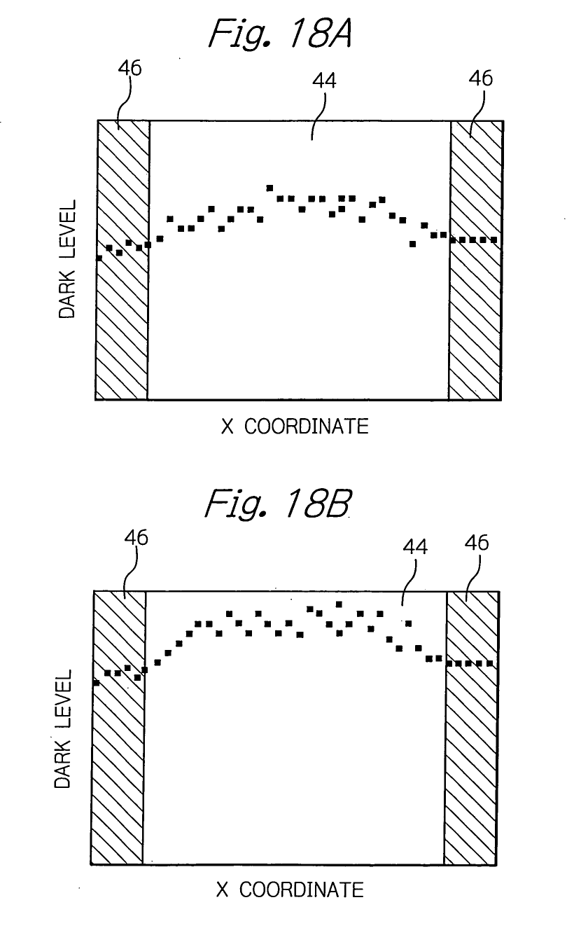

The dark level under the entirely shaded condition is as shown in FIG. 17A and may increase as shown in FIGS. 18A and 18B. The latter level increase occurs when the exposure time is extended or the temperature is increased or the like. The dark level is preferably recorded in the memories 28 and/or 112 for each condition.

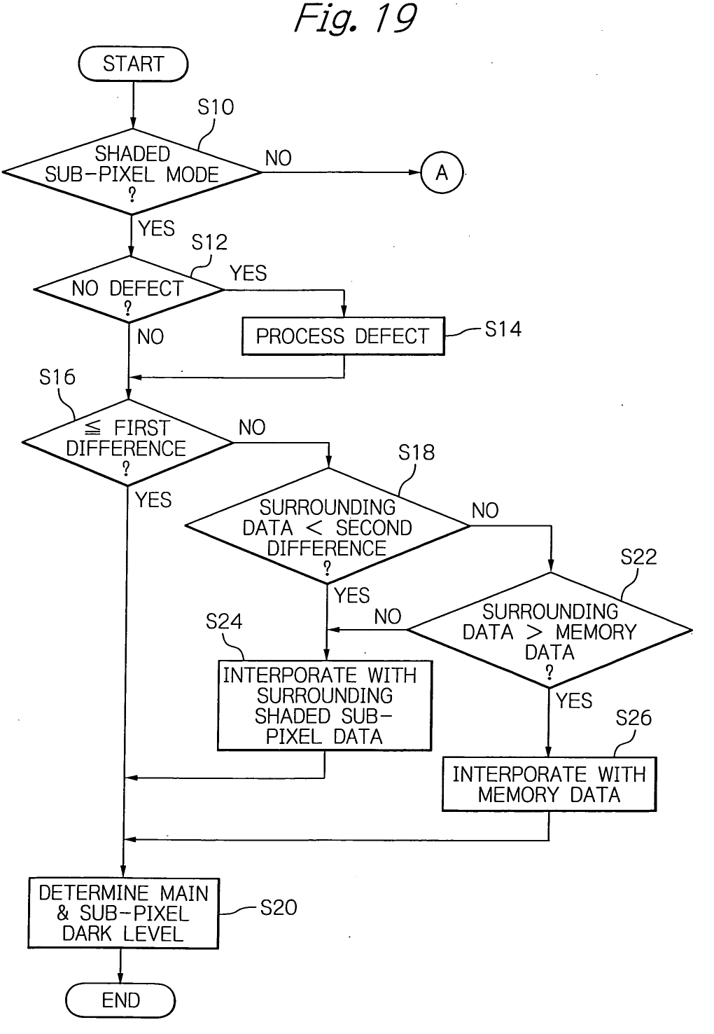

A description is given of how the digital camera 10 using the CCD 40 determines, in the shaded sub-pixel mode, the dark level using the shaded sub-pixel. As shown in FIG. 19, it is first determined whether or not the shaded sub-pixel mode is selected (step S10). The determination is carried out for the entire imaging surface, or all pixels. If the shaded sub-pixel mode is not selected (NO), then the control passes via the connector A to other modes. If the shaded sub-pixel mode is selected (YES), then the control passes to a determination on whether or not a flaw exists, i.e., to step S12.

It is then determined whether or not flaw exists (step S12). The shaded sub-pixel defect address memory 112 is accessed and is checked for a coordinate data corresponding to a flaw that is to be found when sampling is carried out at a Y coordinate in the horizontal direction. If a flaw exists (YES), then the control passes to a flaw correspondence process, i.e., to step S14. If a flaw does not exist (NO), then the control passes to a level determination process, i.e., to step S16.

The flaw correspondence process (step S14) deletes, when the corresponding flaw coordinate exists in the memory 112, the dark data of the flaw coordinate. The flaw correspondence process then allows the shaded sub-pixel interpolator 114 to interpolate the dark data of the shaded sub-pixel that corresponds to the flaw coordinate based on the data from the vicinity shaded sub-pixel. The flaw correspondence process then records the interpolation in the shaded sub-pixel defect address memory 112.

The dark level outputted by the shaded sub-pixel is then determined (step S16). The dark level determination allows the shaded sub-pixel level determination portion 116 to determine whether the dark data from the relevant shaded sub-pixel and predefined dark data from the shaded sub-pixel differ by the first difference or less. If the dark data difference is more than the first difference (NO), then the control passes to a vicinity level determination, i.e., to step S18. If the dark data difference is the first difference or less (YES), the dark data from the relevant shaded sub-pixel is determined to be appropriate as the dark level. The control then passes to a dark level determination process, i.e., to step S20.

The vicinity level determination allows the vicinity comparator 118 to determine whether or not the pixel data of the vicinity shaded sub-pixels differ by less than the second difference (step S18). If the pixel data of the vicinity shaded sub-pixels differ by the second difference or more (NO), the vicinity comparator 118 passes to a dark level selection process, i.e., to step S22. If the pixel data of the vicinity shaded sub-pixels differ by less than the second difference (YES), the control passes to a vicinity interpolation process of the shaded sub-pixel (step S24).

The dark level selection process (S22) preferably compares the dark level in the vicinity of the shaded sub-pixel with the reference dark data recorded in the reference dark data memory 120 to obtain a measurement (dark level) under the entirely shaded condition. The selection process uses, if the vicinity dark data is larger than the reference dark data (YES), the reference dark data as the appropriate data, and passes to a reference interpolation process of the shaded sub-pixel (step S26). If the vicinity dark data is the reference dark data or less (NO), then the control passes to a vicinity interpolation process, i.e., to step S24.

The vicinity interpolation process of the shaded sub-pixel allows the shaded sub-pixel interpolator 114 to determine that the dark data from the shaded sub-pixels in the vicinity of the relevant shaded sub-pixel are appropriate, and interpolate, based on these dark data, the dark data of the relevant shaded sub-pixel (step S24). The reference interpolation process of the shaded sub-pixel allows the shaded sub-pixel interpolator 114 to interpolate, based on the reference dark data read out from the reference dark data memory 120, the dark data of the relevant shaded sub-pixel (step S26). The reference dark data are the dark data acquired at a plurality of situations under the entirely shaded condition. The plurality of situations include different exposure times and different temperatures and the like.

After the dark level determination, and the vicinity interpolation and reference interpolation processes of the shaded sub-pixel are carried out, then, using the dark level determined to be appropriate, the reference dark level creator 108 generates the dark data of the shaded sub-pixel as the reference signal (step S20). The generated reference dark data is stored in the reference dark data memory 120. Then, this mode is ended.

The process described above is requested during the actual shooting because, first, cosmic rays or the like may cause additional flaws in the shaded sub-pixels, and second, smears may leak light into the vertical transfer path 70, which light may prevent the shaded sub-pixel from maintaining the dark level. The vicinity interpolation process of the shaded sub-pixel is effective for the first cause. The reference interpolation process of the shaded sub-pixel is effective for the second cause. This is because the dark levels of the shaded sub-pixels in the vicinity of the relevant shaded sub-pixel may also generate a large amount of signal.

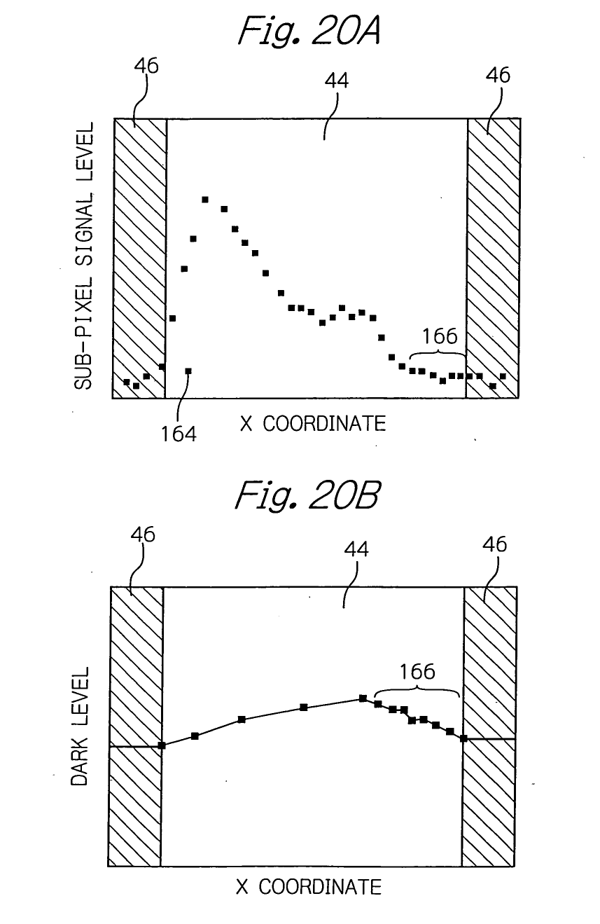

The actual shooting may encounter a scene totally having a small amount of signal or a scene having a high contrast or the like. In these scenes, the non-shaded sub-pixels output signals as shown in FIG. 20A during sampling at a Y coordinate in the horizontal direction. Depending on the scene, the CCD 40 may have a range 166 where the CCD 40 may generate signal levels as low as the signal level 164 of the shaded sub-pixel. With respect to the dark level, FIG. 20B shows that even the non-shaded sub-pixels' dark levels in the range 166 are as high as the dark level of the shaded sub-pixel.

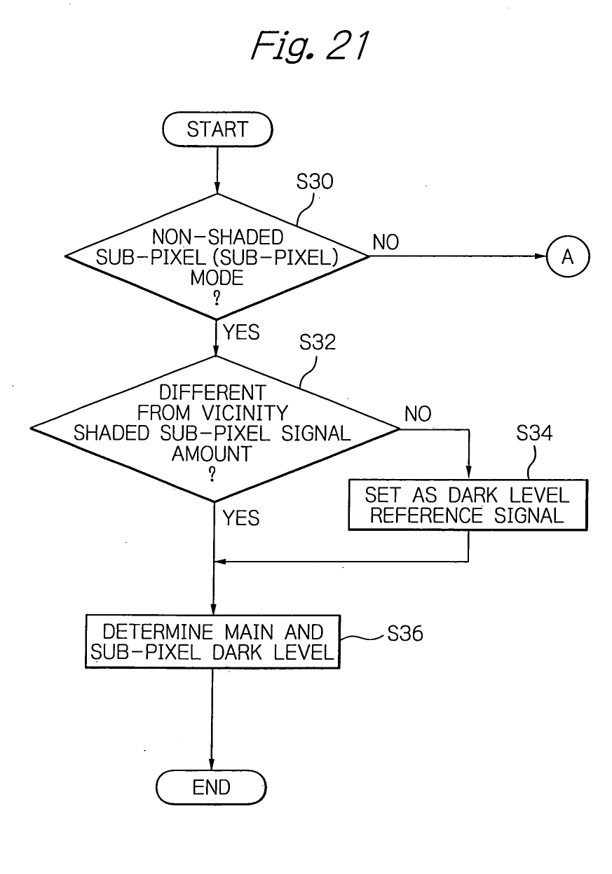

Even the non-shaded sub-pixel is therefore preferably handled as in the shaded sub-pixel when determining the dark level. FIG. 21 briefly shows the procedure. The digital camera 10 first causes the scene determination function portion 138 in the system controller 20, for example, to carry out the scene determination. If it is determined that the scene includes particularly the dark area at a ratio higher than a predetermined ratio, the control passes to the selection of the non-shaded sub-pixel mode, i.e., the (normal) sub-pixel mode. The digital camera 10 determines whether or not the non-shaded sub-pixel mode is selected (step S30). If the non-shaded sub-pixel mode is not selected (NO), then the control passes via the connector A to other modes. If the non-shaded sub-pixel mode is selected (YES), then the control passes to a signal amount determination, i.e., to step S32.

The amount of signal from the non-shaded sub-pixel is then determined. If it is determined that the relevant non-shaded sub-pixel provides an amount of signal similar to that of the vicinity non-shaded sub-pixels (NO), then the control passes to a reference signal setting, i.e., to step S34. If it is determined that the relevant non-shaded sub-pixel provides an amount of signal obviously different from those of the vicinity non-shaded sub-pixels (YES), then the control passes to a dark level determination process, i.e., to step S36.

The reference signal setting sets the dark level for the non-shaded sub-pixel, i.e., the normal sub-pixel as the reference signal (step S34). The digital camera 10 then passes to a dark level determination process, i.e., to step S36.

The dark level determination process considers the dark levels both of the non-shaded sub-pixel and in the range 166 to generate the dark levels of the main and sub-pixels as the reference signal (reference dark data) (step S36). The generated reference dark data is stored in the reference dark data memory 120. And then, this mode is ended.

As described above, the digital camera 10 handles even the non-shaded sub-pixels as in the shaded sub-pixels depending on the scene, and regards the non-shaded sub-pixels as the pixels that may correspond to the shaded state, thus increasing the shaded sub-pixels to further improve the accuracy of the reference dark level.

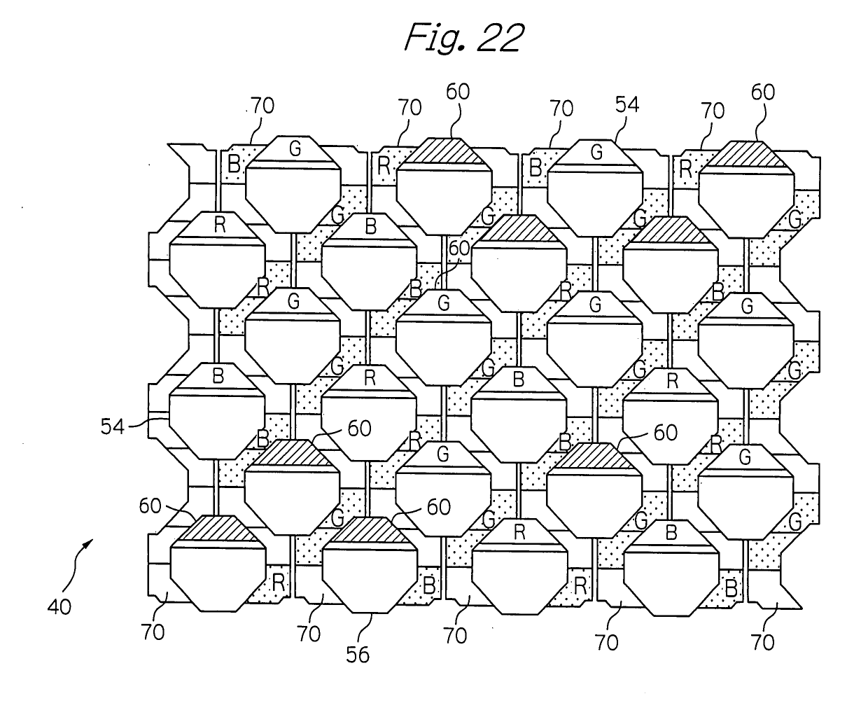

A description is given of how the signal charges accumulated from the main and sub-pixels of each photosensitive device 54 in the CCD 40 are read out in the multiple fields. Each photosensitive device 54 reads the main and sub-pixels individually. The CCD 40 reads out first, as shown in FIG. 22, the signal charges that are accumulated from the main pixel of the photosensitive device 54 in two packets in the vertical transfer path 70. The letters R, G, and B shown in the vertical transfer path 70 denote the colors that correspond to the signal charge color filter segments R, G, and B. The signal charges of the main and sub-pixels are denoted by the larger uppercase letter and the smaller uppercase letter, respectively. The signal charges from the main pixels are read out in one field period.

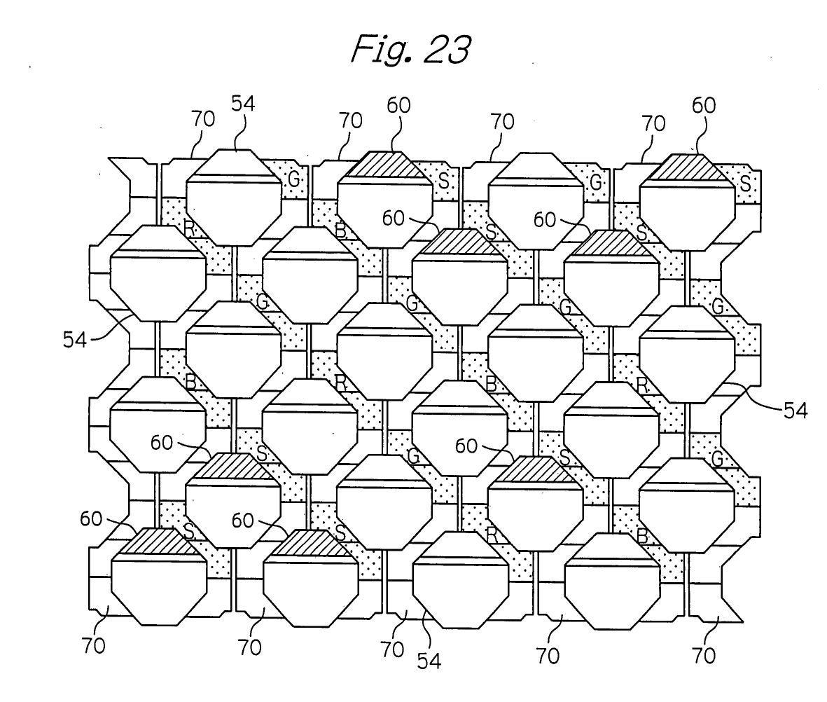

The signal charges from the sub-pixels are then read into the vertical transfer path 70, as shown in FIG. 23. The signal charges readout from the shaded sub-pixels, i.e., the dark currents, are denoted by the symbols S. The signal charges from the sub-pixels are also read out in one field period. The digital camera 10 thus reads all pixels during the two field reading.

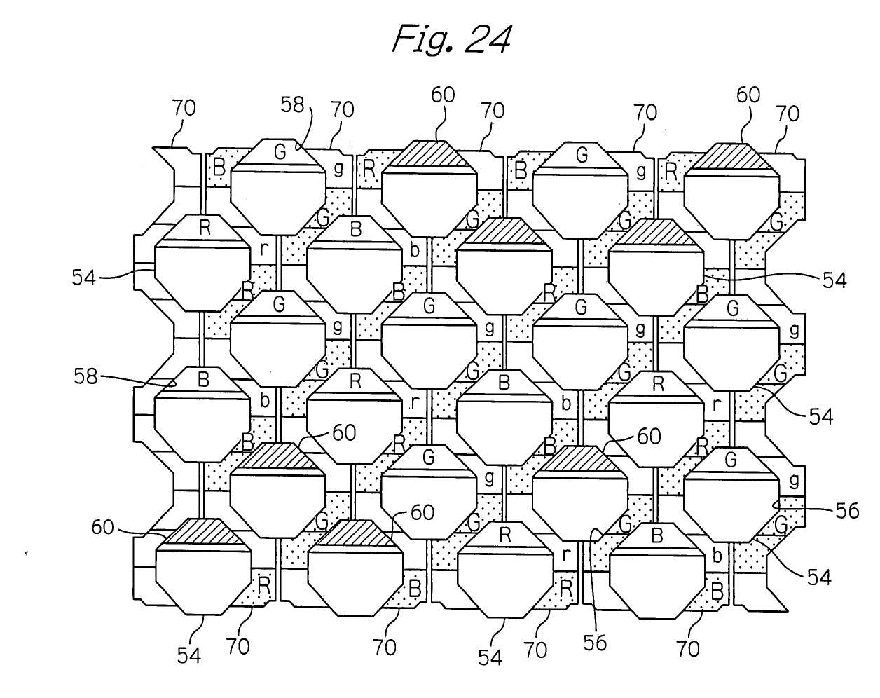

During the reading from the main pixels, the CCD 40 also develops disadvantageously the signals from the sub-pixels. This is because the photosensitive device 54 has the read electrodes of the main and sub-pixels in close proximity. FIG. 24 shows the signal charges read out from the main and sub-pixels in this way.

The signal charges leaking into the vertical transfer path 70 and leak amount are denoted by the lowercase letters r, g, b, and s. A combination of the two packets of the main pixel and one packet of the sub-pixel does not cause color mixture because they have the same color.

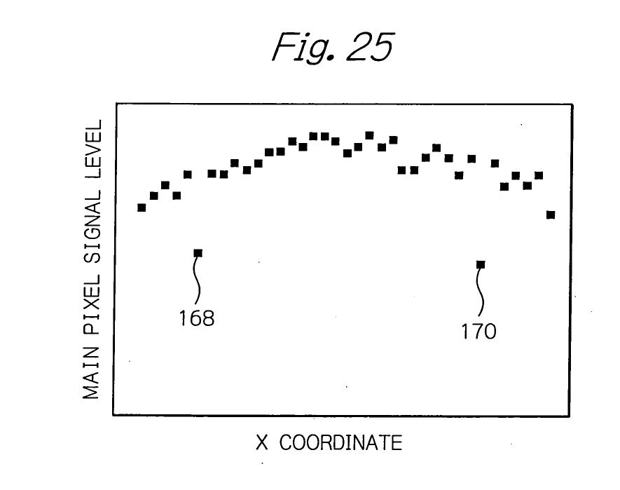

FIG. 25 shows the signal levels of the image of uniform brightness obtained during sampling carried out at a Y coordinate in the horizontal direction. The signal levels indicate the main pixel's levels. FIG. 25 shows that the signal levels 168 and 170 of the main pixels which pair with the shaded sub-pixels have a smaller amount of signal than the signal levels of the main pixels which pair with the non-shaded sub-pixels. This is because the shaded sub-pixels originally have a small amount of signal, so that a small amount of signal leaks from them. In other words, it is because in the image of uniform brightness, the main pixels that pair with the non-shaded sub-pixels receive more signal leaks from the sub-pixels than the main pixels that pair with the shaded sub-pixels. If the leak amount from the shaded sub-pixels is known in advance, the leak amount from the non-shaded sub-pixels may be corrected.

Based on this idea, the sub-signal processor 98 allows the leak acquirer 124 to acquire the leak amount in advance. More specifically, the data acquirer 128 first acquires the signal level A of the main pixel that pairs with the shaded sub-pixel. The vicinity signal acquirer 130 then acquires the signal level B of the main pixel that pairs with the non-shaded sub-pixel in the vicinity of the relevant main pixel, i.e., the main pixel that pairs with the shaded sub-pixel. The leak signal amount calculator 132 then calculates the signal level (B-A) as the leak amount from the non-shaded sub-pixel. The leak corrector 126 then corrects the signal level from the main pixel that pairs with the non-shaded sub-pixel with the calculated leak amount from the non-shaded sub-pixel.

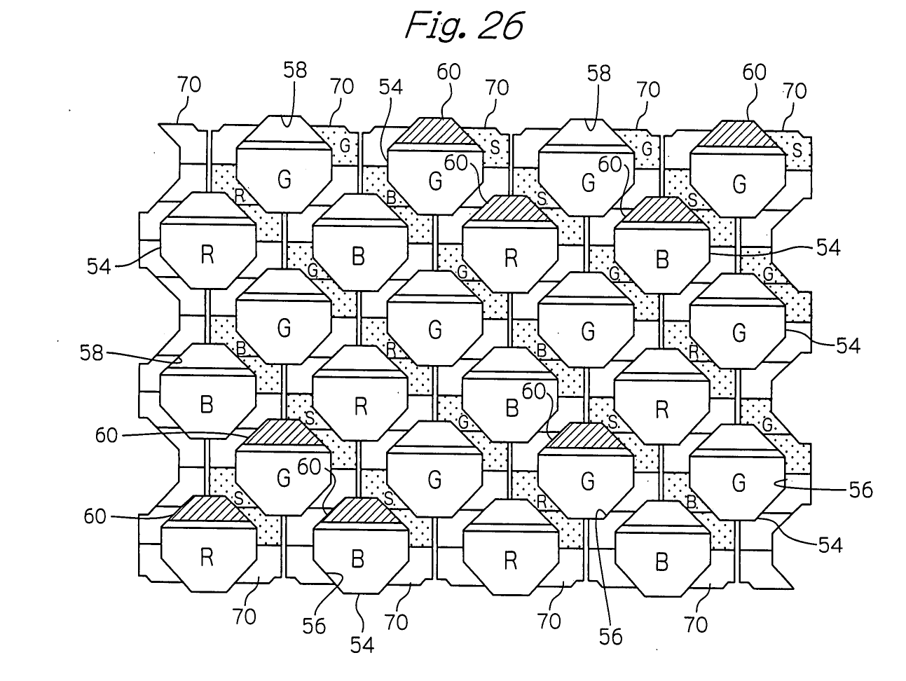

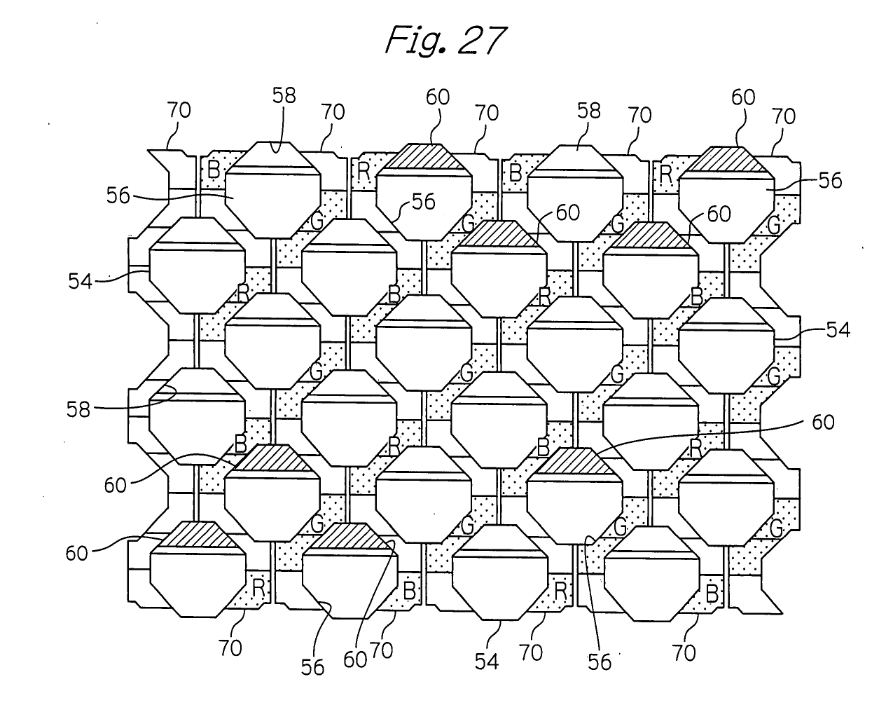

Next, as shown in FIG. 7, for a plurality of continuous images having no substantial time difference therebetween, such as in the continuous shooting or motion picture, the signal charges are read out from the main and sub-pixels in a varied order. For example, as shown in FIGS. 22 and 23, the signal charges are read out in two fields with the main pixel's signals first read out and the sub-pixel's signals second read out. After the two-field reading, the signal charges are read out in two fields with the sub-pixel's signals first read out and the main pixel's signals second read out, as shown in FIGS. 26 and 27.

In such alternate reading, the main pixel is affected differently by the vertical transfer path 70. For the continuous shooting without substantial time difference, the dark current of the vertical transfer path 70 is corrected in the manner to read as follows. In the first two fields in the shooting, the reference dark data from the shaded sub-pixel obtained in the second field is applied to the main pixel in the first field. In the next two fields in the shooting, the reference dark data from the shaded sub-pixel obtained in the third field is applied to the main pixel in the fourth field. The correction is carried out by the dark corrector 106.

As described above, the image data obtained by the CCD 40 is processed in the signal processor 18 to provide, in the areas far from the optical black area, more accurate dark correction than the conventional technologies. The images may be dark corrected and the leak amount of the signal charges may be corrected to further improve the image quality of the shot image.

The entire disclosure of Japanese patent application No. 2006-11126 filed on Jan. 19, 2006, including the specification, claims, accompanying drawings and abstract of the disclosure is incorporated herein by reference in its entirety.

While the present invention has been described with reference to the particular illustrative embodiments, it is not to be restricted by the embodiments. It is to be appreciated that those skilled in the art can change or modify the embodiments without departing from the scope and spirit of the present invention.

What is claimed is:

1. An image sensor comprising:
a plurality of photosensitive devices that photoelectrically convert incident light from a field of view to signal charges, each of the photosensitive devices having a first photosensitive area defined as a main pixel and a second photosensitive area defined as a sub-pixel and smaller than the first photosensitive area;
a color filter segment of a predetermined color that passes a predetermined wavelength range included in the incident light, and is provided correspondingly to said main pixel and said sub-pixel; and
a column transfer path that selectively transfers, in a vertical direction, the signal charges generated by said main and sub-pixels and read into said column transfer path,
said photosensitive devices including an effective area for being finally used to produce an image of the field of view, ones of said sub-pixels in the effective area being shaded to form shaded sub-pixels.

2. The image sensor in accordance with claim 1, wherein said main pixel and said sub-pixel are combined to form a photosensitive cell.

3. The image sensor in accordance with claim 1, further comprising a micro lens having a light-collection function provided on a side of each of said main pixel and said sub-pixel to which the incident light comes, wherein
said micro lens has a first optical system over the first photosensitive area and a second optical system over the second photosensitive area, the second optical system having a curvature larger than the first optical system.

4. The image sensor in accordance with claim 1, wherein ones of said sub-pixels over which a color filter segment that passes a shorter wavelength range of the incident light is provided are shaded to form said shaded sub-pixels at a ratio higher than other ones of said sub-pixels over which a color filter segment that passes a wavelength range other than the shorter wavelength.

5. The image sensor in accordance with claim 1, wherein ones of said sub-pixels over which said color filter segments of the predetermined color are mostly provided are more shaded than pixels over which other colors are provided.

6. An imaging system comprising:
an image sensor; and
a signal processor that carries out signal processing on image data obtained by said image sensor,
said image sensor comprising:
a plurality of photosensitive devices that photoelectrically convert incident light from a field of view to signal charges, each of the photosensitive devices having a first photosensitive area defined as a main pixel and a second photosensitive area defined as a sub-pixel and smaller than the first photosensitive area;
a color filter segment of a predetermined color that passes a predetermined wavelength range included in the incident light, and is provided correspondingly to said main pixel and said sub-pixel; and
a column transfer path that selectively transfers, in a vertical direction, the signal charges generated by said main and sub-pixels and read into said column transfer,
said photosensitive devices including an effective area for being finally used to produce an image of the field of view, ones of said sub-pixels in the effective area being shaded to form shaded sub-pixels.

7. The system in accordance with claim 6, wherein a dark current obtained from said shaded sub-pixel is used as a dark level to correct the image data in the effective area with the dark level.

8. The system in accordance with claim 6, wherein a ratio of a photosensitive area between said main pixel and said sub-pixel is used to determine the dark level and correct the image data in the effective area with the dark level.

9. The system in accordance with claim 6, wherein when a temperature in said system is equal to or more than a predetermined value, the image data in the effective area is corrected with the dark level previously measured for each temperature.

10. The system in accordance with claim 6, wherein said signal processor comprises an interpolator that interpolates the pixel data of the sub-pixel originally obtained in said shaded sub-pixel with pixel data from said sub-pixel or main pixel in a vicinity of said shaded sub-pixel.

11. The system in accordance with claim 6, wherein said signal processor comprises a circuit that, when said shaded sub-pixel has a flaw, removes pixel data of said shaded sub-pixel from reference dark data that is a reference of the dark level to create the reference dark data.

12. The system in accordance with claim 6, wherein said signal processor comprises a level determinator that, when pixel data of a relevant shaded sub-pixel and predefined pixel data differ from each other by more than a first difference value, removes the pixel data of the relevant shaded sub-pixel from reference dark data that is a reference of the dark level.

13. The system in accordance with claim 6, wherein said signal processor comprises a vicinity comparator that compares pixel data of a relevant shaded sub-pixel with pixel data of a shaded sub-pixel in a vicinity of said relevant shaded sub-pixel to determine whether or not the data differ from each other less than a second difference value.

14. The system in accordance with claim 13, wherein
in a sub-pixel mode for a scene where a dark area is more than a predetermined ratio, and when the pixel data of the relevant shaded sub-pixel and the pixel data of a vicinity shaded sub-pixel differ from each other less than the second difference value, said vicinity comparator stores the pixel data of the relevant shaded sub-pixel in a memory as the reference dark data,
said signal processor carrying dark correction on the supplied image data, based on the obtained reference dark data.

15. The system in accordance with claim 6, wherein said signal processor comprises a leak-measurement device that measures, as leak data, signal charges leaking from said sub-pixel during reading of the signal charges from said main pixel,
said leak-measurement device comprising:
a first measurement device that measures pixel data from said main pixel that pairs with said shaded sub-pixel;
a second measurement device that measures pixel data from said main pixel that pairs with said sub-pixel in a vicinity of said main pixel that pairs with said shaded sub-pixel; and
a calculator that calculates, as the leak data, a difference between pixel data measured by said second measurement device and pixel data measured by said first measurement device.

16. The system in accordance with claim 6, wherein a signal from said image sensor is read out in at least two fields in such a manner that, in a mode where at least two frames are continuously shot, the signals are readout from said main pixel and said sub-pixel in an order in a current frame that is opposite to an order in a previous frame.

17. The system in accordance with claim 6, wherein said image sensor comprises a photosensitive cell formed with said main pixel and said sub-pixel combined.

18. The system in accordance with claim 6, wherein
said image sensor comprises a micro lens having a light-collection function provided on a side of each of said main pixel and said sub-pixel to which the incident light comes,
said micro lens having a first optical system over a photosensitive area of said main pixel and a second optical system over a photosensitive area of said sub-pixel, the second optical system having a curvature larger than the first optical system.

19. The system in accordance with claim 6, wherein in said image sensor, ones of said sub-pixels over which a color filter segment that passes a shorter wavelength range of the incident light is provided are shaded to form said shaded sub-pixels at a ratio higher than other ones of said sub-pixels over which a color filter segment that passes a wavelength range other than the shorter wavelength.

20. The system in accordance with claim 6, wherein in said image sensor, sub-pixels over which said color filter segments of the predetermined color are mostly provided are more shaded than pixels over which other colors are provided.
